(19) United States
(12) Patent Application Publication
(10) Pub. No.: US 2023/0295477 A1
(43) Pub. Date: Sep. 21, 2023

(54) ADHESIVE COMPOSITION FOR COATING-TYPE POLARIZATION ELEMENTS, ADHESIVE SHEET FOR COATING-TYPE POLARIZATION ELEMENTS, ADHESIVE SHEET FOR IMAGE DISPLAY DEVICE CONSTITUTING MEMBERS, ADHESIVE SHEET WITH MOLD RELEASE FILMS, ADHESIVE SHEET WITH IMAGE DISPLAY DEVICE CONSTITUTING MEMBER, LAMINATE SHEET, COATING-TYPE POLARIZATION ELEMENT WITH ADHESIVE LAYER, ADHESIVE SHEET WITH POLARIZATION ELEMENT, AND IMAGE DISPLAY DEVICE

(71) Applicant: Mitsubishi Chemical Corporation, Tokyo (JP)

(72) Inventors: Kohei Hirose, Tokyo (JP); Terutsune Osawa, Tokyo (JP)

(73) Assignee: Mitsubishi Chemical Corporation, Tokyo (JP)

(21) Appl. No.: 18/201,936

(22) Filed: May 25, 2023

Related U.S. Application Data
(63) Continuation of application No. PCT/JP2021/037654, filed on Oct. 12, 2021.

(30) Foreign Application Priority Data
Nov. 27, 2020 (JP) 2020-196912
Nov. 27, 2020 (JP) 2020-196913

(51) Int. Cl. C09J 133/08; C09J 4/00; C09J 7/38; C09J 11/06

(52) U.S. Cl. CPC C09J 133/08; C09J 4/00; C09J 7/385; C09J 11/06; G02B 5/30

(57) ABSTRACT

Provided is an adhesive composition for coating-type polarization elements containing a (meta)acrylic polymer (A), an ultraviolet absorber (B), and a radical polymerization initiator (C), wherein an adhesive layer formed from the adhesive composition has a transmittance at a wavelength of 400 nm of 50% or less, and the adhesive composition can be used in combination with a coating-type polarization element to prevent the coating-type polarization element from deteriorating polarization performance over time due to exposure.

### TECHNICAL FIELD

The present invention relates to an adhesive composition that can be suitably used for organic electroluminescence (hereinafter also referred to as “organic EL”) In particular, the present invention relates to an adhesive composition that can be suitably used for coating-type polarization elements, an adhesive sheet for coating-type polarization elements formed from the adhesive composition, an adhesive sheet with a polarization element including a coating-type polarization element, an image display device using the adhesive sheet, a coating-type polarization element with an adhesive layer having an adhesive layer formed from the adhesive composition, and an image display device using the coating-type polarization element with an adhesive layer. The present invention also relates to an adhesive sheet for image display device constituting members that can be suitably used for laminating image display device constituent members, as well as an adhesive sheet with mold release films, an adhesive sheet with an image display device constituting member, a laminate sheet, and an image display device using the adhesive sheet for image display device constituting members.

### BACKGROUND ART

In recent years, with the trend toward thinning and weight reduction of image display devices such as liquid crystal display devices and organic EL display devices, optically anisotropic members such as polarization plates and retardation plates that constitute image display devices are also required to be thin.

Conventional polarization plates generally have a structure in which a polyvinyl alcohol (PVA) film is sandwiched between protective films such as triacetyl cellulose (TAC) films, and coated with an adhesive or laminated with an adhesive sheet. For example, polarization plates having a laminate configuration of adhesive layer/protective film/polarization film (polarizer)/protective film/adhesive layer, or adhesive layer/protective film/polarization film (polarizer)/retardation plate/adhesive layer are known.

However, such conventional polarization plates are extremely fragile because they use a polarizer made of stretched polyvinyl alcohol (PVA) film, and they are required to be sandwiched between two protective films, which limits their thinness.

Therefore, as a means of thinning polarization elements such as polarization plates, the following coating-type polarization elements are attracting attention.

A liquid crystal compound having a polymerizable functional group (also referred to as “polymerizable liquid crystal compound”) has both properties of a polymerizable monomer and a liquid crystal, and when it is polymerized and cured in an oriented state, a cured product composed of a polymer with a fixed orientation, that is, an optically anisotropic material, can be obtained.

Therefore, polarization films having optical anisotropy can be formed by coating an optically anisotropic composition containing a polymerizable liquid crystal compound on a substrate and curing the composition in an oriented state. Polarization elements thus obtained are generally called coating-type polarization elements in many cases.

On the other hand, adhesive sheets containing an ultraviolet absorber are known to be used between a surface protection panel and an image display module to suppress photodegradation of image display device constituting members.

For example, Patent Literature 1 discloses an adhesive sheet including an acrylic adhesive layer and having a b* value of 0.42 or less and a light transmittance at a wavelength of 350 nm of 5% or less.

Patent Literature 2 discloses an ultraviolet curable acrylic adhesive layer, which is arranged between a cover glass or a cover plastic and a polarization film in an image display device, with a transmittance at a wavelength of 380 nm of 40% or less and a transmittance at a wavelength of 400 nm of 30% or more.

### CITATION LIST

### Patent Literature

Patent Literature 1: Japanese Patent Laid-Open No. 2019-214722
Patent Literature 2: Japanese Patent Laid-Open No. 2016-155981

### SUMMARY OF THE INVENTION

### Problem to be Solved by the Invention

The coating-type polarization elements described above can be thinner than conventional polarization elements because the films can be formed by coating.

However, such coating-type polarization elements are easily degraded by light, and thus have the problem of polarization performance deteriorating over time due to ambient light and other light.

In addition, not only polarization elements, but also various optical members such as iodine and dichroic organic dyes used in polarization plates, as well as liquid crystal panels and organic EL elements used in image display devices, have the problem of insufficient light resistance.

Then, it is conceivable to use an adhesive sheet containing an ultraviolet absorber in a coating-type polarization element, as described above.

However, the transparent adhesives for image display devices having light absorption functions in Patent Literatures 1 and 2 are not designed to be used in combination with a coating-type polarization element, and thus, when used in a coating-type polarization element, it is difficult to prevent the coating-type polarization element from deteriorating in polarization performance over time due to ambient light and other light.

Accordingly, an object of the present invention is to provide an adhesive composition or an adhesive sheet for coating-type polarization elements that, when used in combination with a coating-type polarization element, capable of preventing the coating-type polarization element from deteriorating in polarization performance over time due to exposure.

The transparent adhesives for image display devices having light absorption functions in Patent Literatures 1 and 2 supplement the function of a protective film layer that protects a polarization plate from ultraviolet rays, that is, a protective film layer containing an ultraviolet absorber. Then, in order to accommodate further thinning and weight reduction of image display devices, it is necessary to suppress photodegradation of optical members without providing a protective film layer, and for this purpose, the adhesives themselves are required to have light resistance reliability.

Accordingly, another object of the present invention is to provide an adhesive sheet for image display device constituting members having excellent light resistance reliability to accommodate thinning and weight reduction of image display devices.

### Means for Solving Problem

To solve such problems, the present invention proposes an adhesive composition for coating-type polarization elements containing a (meta)acrylic polymer (A), an ultraviolet absorber (B), and a radical polymerization initiator (C), wherein an adhesive layer formed from the adhesive composition has a transmittance at a wavelength of 400 nm of 50% or less; and an adhesive sheet for coating-type polarization elements including an adhesive layer formed using the composition.

The present invention also proposes an adhesive sheet for image display device constituting members, which is formed from an adhesive composition containing a (meta)acrylic polymer (A), a hydroxy group-containing benzophenone compound (B1), and a radical polymerization initiator (C) and has a light transmittance at a wavelength of 400 nm of less than 30%.

### Effect of the Invention

The adhesive composition for coating-type polarization elements or the adhesive sheet for coating-type polarization elements according to the present invention can be used in combination with a coating-type polarization element to prevent the coating-type polarization element from deteriorating in polarization performance over time due to ambient light and other light. Therefore, the coating-type polarization element can be laminated and integrated with other image display device constituting members without using a protective film as in the past, and can also be prevented from photodegradation, thereby contributing to thinning, weight reduction, and improved resistance to photodegradation of image display devices.

The adhesive sheet for image display device constituting members proposed by the present invention has excellent light resistance reliability, and can be thus laminated and integrated with an image display device constituting member without providing a protective film layer that protects a polarization plate from ultraviolet rays, that is, a protective film layer containing an ultraviolet absorber as in the past. Furthermore, the image display device constituting member can also be prevented from photodegradation, thereby contributing to thinning, weight reduction, and improved resistance to photodegradation of image display devices.

### BRIEF DESCRIPTION OF DRAWINGS

FIG. 1 is a cross-sectional view showing an example of an adhesive sheet with a polarization element or an adhesive sheet with an image display device constituting member according to the present invention.

FIG. 2 is a cross-sectional view showing an example of an image display device according to the present invention.

FIG. 3 is a cross-sectional view showing an example of an image display device according to the present invention.

FIG. 4 is a cross-sectional view showing an example of an image display device according to the present invention.

FIG. 5 is a cross-sectional view showing an example of an image display device according to the present invention.

FIG. 6 is a cross-sectional view showing an example of an adhesive sheet with mold release films according to the present invention.

FIG. 7 is a cross-sectional view showing an example of a laminate sheet according to the present invention.

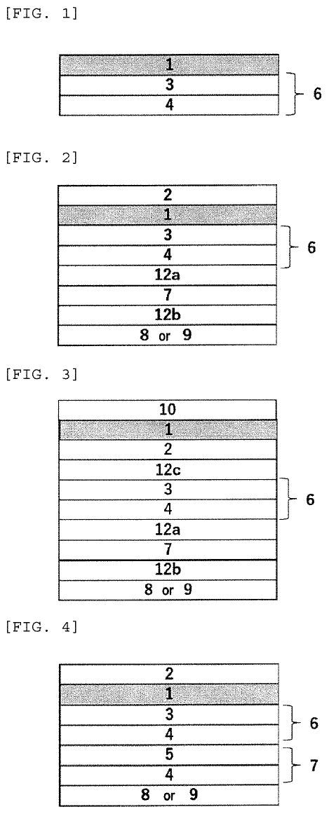

### MODE(S) FOR CARRYING OUT THE INVENTION

Next, the present invention will be described based on exemplary embodiments. However, the present invention is not limited to the embodiments that will be described below.

<<Present Adhesive Composition I>>

An adhesive composition I for coating-type polarization elements (referred to as “present adhesive composition I”) according to an example of the embodiment of the present invention contains a (meta)acrylic polymer (A), an ultraviolet absorber (B), and a radical polymerization initiator (C), and optionally contains a polyfunctional (meth)acrylate (D) and other components.

As used herein, the term “(meth)acrylic polymer” includes an acrylic copolymer and a methacrylic copolymer; the term “(meth)acrylate” includes acrylate and methacrylate; and the term “(meth)acryloyl” includes acryloyl and methacryloyl.

Also, the term “polarization element” as used herein means an optical member having optical anisotropy, and the term “coating-type polarization element” means a laminate including a film formed by coating an optically anisotropic composition containing a liquid crystal compound. Examples of the liquid crystal compound include polymerizable liquid crystal compounds, polymer liquid crystal compounds, and lyotropic liquid crystal compounds. For example, a cured product obtained by coating an optically anisotropic composition containing a polymerizable liquid crystal compound on a substrate and curing the composition in an oriented state can be used as a polarization element. In this case, the substrate may or may not be included.

The present adhesive composition I may be cured by heat or by active energy rays, as described below. In particular, those that are cured by active energy rays are preferred because they do not require aging and are excellent in productivity.

The present adhesive composition I may be cured in multiple stages, as described below.

It is usually difficult to adopt an active energy ray curing system for an adhesive sheet containing an ultraviolet absorber, because when the sheet is cured by active energy rays, the ultraviolet absorber interferes with the curing by the active energy rays. However, when it is daringly applied in the present invention, a good adhesive sheet can be obtained.

<(Meth)Acrylic Polymer (A)>

Examples of the (meth)acrylic polymer (A) include an alkyl (meth)acrylate homopolymer and a copolymer obtained by polymerizing a monomer component that is copolymerizable with an alkyl (meth)acrylate homopolymer.

Examples of the copolymer include those obtained by copolymerizing an alkyl (meth)acrylate (a1) having 4 to 18 alkyl group carbon atoms as a main component with a monomer component copolymerizable therewith.

The term “main component” means a component that significantly affects the properties of the (meth)acrylic polymer (A), and the content of the component is usually 30% by mass or more, preferably 35% by mass or more, more preferably 50% by mass or more, and particularly preferably 60% by mass or more, relative to the total of the (meth)acrylic polymer (A).

The (meth)acrylic polymer (A) may contain two or more different (meth)acrylic polymers.

Examples of the “alkyl (meth)acrylate (a1) having 4 to 18 alkyl group carbon atoms” include linear alkyl (meth)acrylates such as n-butyl (meth)acrylate, pentyl (meth)acrylate, hexyl (meth)acrylate, heptyl (meth)acrylate, n-octyl (meth)acrylate, nonyl (meth)acrylate, decyl (meth)acrylate, undecyl (meth)acrylate acrylate, lauryl (meth)acrylate, tridecyl (meth)acrylate, tetradecyl (meth)acrylate, cetyl (meth)acrylate, and stearyl (meth)acrylate; branched alkyl (meth)acrylates such as isobutyl (meth)acrylate, sec-butyl (meth)acrylate, t-butyl (meth)acrylate, isopentyl (meth)acrylate, neopentyl (meth)acrylate, 2-ethylhexyl (meth)acrylate, isooctyl (meth)acrylate, isononyl (meth)acrylate, isodecyl (meth)acrylate, and isostearyl (meth)acrylate; and alicyclic (meth)acrylates such as cyclohexyl (meth)acrylate, t-butylcyclohexyl (meth)acrylate, 3,5,5-trimethylcyclohexane (meth)acrylate, dicyclopentanyl (meth)acrylate, dicyclopentenyl (meth)acrylate, dicyclopentenyloxyethyl (meth)acrylate, and isobornyl (meth)acrylate. These may be used alone or in combination of two or more types thereof.

The content of the alkyl (meth)acrylate (a1) is preferably 30% by mass or more, more preferably 40% by mass or more, even more preferably 50% by mass or more, particularly preferably 60% by mass or more, and most preferably 65% by mass or more, relative to the total component of the (meth)acrylic polymer (A), from the viewpoint of improving the stress relaxation and heat resistance reliability in forming an adhesive sheet or adhesive layer.

In addition, the content of the alkyl (meth)acrylate (a1) is preferably 90% by mass or less, more preferably 85% by mass or less, even more preferably 80% by mass or less, particularly preferably 75% by mass or less, and most preferably 70% by mass or less, relative to the total component of the (meth)acrylic polymer (A), from the viewpoint of suppressing a decrease in adhesive force.

Examples of the monomer component copolymerizable with the alkyl (meth)acrylate (a1) having 4 to 18 alkyl group carbon atoms include a hydroxy group-containing monomer (a2), a (meth)acrylate monomer or vinyl ester monomer (a3) having 1 to 3 alkyl group carbon atoms, a functional group-containing ethylenically unsaturated monomer (a4) (excluding the hydroxy group-containing monomer (a2)), and other copolymerizable monomers (a5).

Examples of the “hydroxy group-containing monomer (a2)” include primary hydroxy group-containing monomers such as hydroxy (meth) acrylates such as 2-hydroxyethyl (meth)acrylate, 4-hydroxybutyl (meth)acrylate, 5-hydroxypentyl (meth)acrylate, 6-hydroxyhexyl (meth)acrylate, and 8-hydroxyoctyl (meth)acrylate, caprolactone-modified monomers such as caprolactone-modified 2-hydroxyethyl (meth)acrylate, oxyalkylene-modified monomers such as diethylene glycol (meth)acrylate and polyethylene glycol (meth)acrylate, and 2-acryloyloxyethyl-2-hydroxyethyl phthalate; secondary hydroxy group-containing monomers such as 2-hydroxypropyl (meth)acrylate, 2-hydroxybutyl (meth)acrylate, and 3-chloro 2-hydroxypropyl (meth)acrylate; and tertiary hydroxy group-containing monomers such as 2,2-dimethyl 2-hydroxyethyl (meth)acrylate. These may be used alone or in combination of two or more types thereof.

Among the hydroxy group-containing monomers (a2), primary hydroxy group-containing monomers, especially 2-hydroxyethyl (meth)acrylate, 4-hydroxybutyl (meth)acrylate, and 2-hydroxypropyl (meth)acrylate are preferred because of their excellent balance of moist heat resistance and heat resistance; and 2-hydroxyethyl (meth)acrylate and 4-hydroxybutyl (meth)acrylate are particularly preferred.

The lower limit of the content of the hydroxy group-containing monomer (a2) is usually 3% by mass or more, preferably 5% by mass or more, more preferably 8% by mass or more, even more preferably 10% by mass or more, and particularly preferably 12% by mass or more, relative to the total component of the (meth)acrylic polymer (A), from the viewpoint of improving the moist heat resistance.

In addition, the upper limit of the content of the hydroxy group-containing monomer (a2) is usually 60% by mass or less, preferably 45% by mass or less, more preferably 35% by mass or less, even more preferably 30% by mass or less, and particularly preferably 25% by mass or less, from the viewpoint of suppressing the self-crosslinking reaction of the adhesive composition and improving the processability and heat resistance reliability.

Examples of the “(meth)acrylate monomer or vinyl ester monomer (a3) having 1 to 3 alkyl group carbon atoms” include methyl (meth)acrylate, ethyl (meth)acrylate, n-propyl (meth)acrylate, isopropyl (meth)acrylate, vinyl propionate, and vinyl acetate. These monomers (a3) may be used alone or in combination of two or more types thereof.

Among the (a3) components, methyl (meth)acrylate and ethyl (meth)acrylate are preferably used from the viewpoint of improving the cohesive force when used as an adhesive.

The lower limit of the content of the (a3) component, if contained, is preferably 5% by mass or more, more preferably 7% by mass or more, and even more preferably 10% by mass or more, relative to the total component of the (meth)acrylic polymer (A), from the viewpoint of improving the cohesive force when used as an adhesive. In addition, the upper limit of the content of the (a3) component, if contained, is preferably 40% by mass or less, more preferably 30% by mass or less, and even more preferably 20% by mass or less, relative to the total component of the (meth)acrylic polymer (A), from the viewpoint of improving the processability.

Examples of the “functional group-containing ethylenically unsaturated monomer (a4)” include a functional group-containing monomer having a nitrogen atom, a carboxy group-containing monomer, an acetoacetyl group-containing monomer, an isocyanate group-containing monomer, and a glycidyl group-containing monomer.

Among them, a functional group-containing monomer having a nitrogen atom is preferred, more preferably an amino group-containing monomer and an amide group-containing monomer, and even more preferably an amino group-containing monomer, in terms of imparting cohesive force and crosslinking promoting effects.

Examples of the “amino group-containing monomer” as the “functional group-containing monomer having a nitrogen atom” include primary amino group-containing (meth)acrylates such as aminomethyl (meth)acrylate and aminoethyl (meth)acrylate; secondary amino group-containing (meth)acrylates such as t-butylaminoethyl (meth)acrylate and t-butylaminopropyl (meth)acrylate; and tertiary amino group-containing (meth)acrylates such as ethylaminoethyl (meth)acrylate, dimethylaminoethyl (meth)acrylate, diethylaminoethyl (meth)acrylate, dimethylaminopropyl (meth)acrylate, diethylaminopropyl (meth)acrylate, and dimethylaminopropyl acrylamide.

Examples of the “amide group-containing monomer” include (meth)acrylamides; N-alkyl (meth)acrylamides such as N-methyl (meth)acrylamide, N-ethyl (meth)acrylamide, N-propyl (meth)acrylamide, N-n-butyl (meth)acrylamide, diacetone (meth)acrylamide, and N,N′-methylenebis (meth)acrylamide; N,N-dialkyl (meth)acrylamides such as N,N-dimethyl (meth)acrylamide, N,N-diethyl (meth)acrylamide, N,N-dipropyl (meth)acrylamide, N,N-ethylmethyl acrylamide, and N,N-diallyl (meth)acrylamide; hydroxyalkyl (meth)acrylamides such as N-hydroxymethyl (meth)acrylamide and N-hydroxyethyl (meth)acrylamide; and alkoxyalkyl (meth)acrylamides such as N-methoxymethyl (meth)acrylamide and N-(n-butoxymethyl) (meth)acrylamide.

Examples of the “carboxy group-containing monomer” include (meth)acrylic acid, carboxyethyl (meth)acrylate, 2-(meth)acryloyloxyethylhexahydrophthalic acid, 2-(meth)acryloyloxypropylhexahydrophthalic acid, 2-(meth)acryloyloxyethylphthalic acid, 2-(meth)acryloyloxypropylphthalic acid, 2-(meth)acryloyloxyethylmaleic acid, 2-(meth)acryloyloxypropylmaleic acid, 2-(meth)acryloyloxyethylsuccinic acid, 2-(meth)acryloyloxypropylsuccinic acid, crotonic acid, fumaric acid, maleic acid, itaconic acid, monomethyl maleic acid, and monomethyl itaconic acid.

Examples of the “acetoacetyl group-containing monomer” include 2-(acetoacetoxy)ethyl (meth)acrylate and allylacetoacetate.

Examples of the “isocyanate group-containing monomer” include 2-acryloyloxyethyl isocyanate, 2-methacryloyloxyethyl isocyanate, and alkylene oxide adducts thereof. The isocyanate group may be protected with blocking agents such as methyl ethyl ketone oxime, 3,5-dimethylpyrazole, 1,2,4-triazole, and diethyl malonate.

Examples of the “glycidyl group-containing monomer” include glycidyl (meth)acrylate and allylglycidyl (meth)acrylate.

These functional group-containing ethylenically unsaturated monomers (a4) may be used alone or in combination of two or more types thereof.

The upper limit of the content of the functional group-containing ethylenically unsaturated monomer (a4) is preferably 30% by mass or less, more preferably 20% by mass or less, even more preferably 10% by mass or less, and particularly preferably 5% by mass or less, relative to the total component of the (meth)acrylic polymer (A), from the viewpoint of improving the heat resistance and light resistance of the adhesive composition.

The (meth)acrylic polymer (A) may optionally contain other copolymerizable monomers (a5) as copolymer components.

Examples of the other copolymerizable monomers (a5) include aromatic (meth)acrylic ester monomers such as phenyl (meth)acrylate, benzyl (meth)acrylate, phenoxyethyl (meth)acrylate, phenyl diethylene glycol (meth)acrylate, phenoxy polyethylene glycol (meth)acrylate, phenoxy polyethylene glycol-polypropylene glycol-(meth)acrylate, and nonylphenol ethylene oxide adduct (meth)acrylate; (meth)acrylic ester monomers having a benzophenone structure such as 4-acryloyloxybenzophenone, 4-acryloyloxyethoxybenzophenone, 4-acryloyloxy-4′-methoxybenzophenone, 4-acryloyloxyethoxy-4′-methoxybenzophenone, 4-acryloyloxy-4′-bromobenzophenone, 4-acryloyloxyethoxy-4′-bromobenzophenone, 4-methacryloyloxybenzophenone, 4-methacryloyloxyethoxybenzophenone, 4-methacryloyloxy-4′-methoxybenzophenone, 4-methacryloyloxyethoxy-4′-methoxybenzophenone, 4-methacryloyloxy-4′-bromobenzophenone, 4-methacryloyloxyethoxy-4′-bromobenzophenone, and mixtures thereof; and vinyl monomers such as acrylonitrile, methacrylonitrile, styrene, α-methylstyrene, vinyl stearate, vinyl chloride, vinylidene chloride, alkyl vinyl ether, vinyl toluene, vinyl pyridine, vinyl pyrrolidone, itaconic acid dialkyl ester, fumaric acid dialkyl ester, allyl alcohol, acrylic chloride, methyl vinyl ketone, N-acrylamidomethyltrimethylammonium chloride, allyltrimethylammonium chloride, and dimethyl allyl vinyl ketone. These may be used alone or in combination of two or more types thereof.

The (meth)acrylic polymer (A) may have a photoactive site, such as a polymerizable carbon double bond group, introduced into the side chain. With this configuration, the present adhesive composition I can be crosslinked by radical polymerization even when the present adhesive composition I contains no polyfunctional (meth)acrylate (D).

Moreover, the crosslinking sensitivity of the present adhesive composition I can be increased, so that the present adhesive composition I can be crosslinked by irradiation with lower energy active energy rays to impart cohesive force and heat resistance.

Examples of the method for introducing a polymerizable carbon double bond group into the side chain of the (meth)acrylic polymer (A) include a method of preparing a copolymer containing the hydroxy group-containing monomer (a2) or the functional group-containing ethylenically unsaturated monomer (a4) as copolymer components, and then subjecting a compound (a6) having a functional group capable of reacting with these functional groups and a polymerizable carbon double bond group to a condensation or addition reaction while maintaining the activity of the polymerizable carbon double bond group.

Examples of the combination of these functional groups include combinations of epoxy group (glycidyl group) and carboxy group, amino group and carboxy group, amino group and isocyanate group, epoxy group (glycidyl group) and amino group, hydroxy group and epoxy group, and hydroxy group and isocyanate group. Among these functional group combinations, a combination of hydroxy group and isocyanate group is preferred because of the ease of reaction control. In particular, a combination in which the copolymer has a hydroxy group and the compound has an isocyanate group is preferred.

Examples of the isocyanate compound having a polymerizable carbon double bond group include 2-acryloyloxyethyl isocyanate, 2-methacryloyloxyethyl isocyanate, and alkylene oxide adducts thereof as described above.

The amount of the compound (a6) added is preferably 10 parts by mass or less, more preferably 8 parts by mass or less, even more preferably 5 parts by mass or less, and particularly preferably 3 parts by mass or less, relative to 100 parts by mass of the (meth)acrylic polymer (A), from the viewpoint of improving the adhesiveness and stress relaxation.

The mass average molecular weight of the (meth)acrylic polymer (A) is preferably 100,000 or more, more preferably 300,000 or more, and even more preferably 500,000 or more, from the viewpoint of obtaining the present adhesive composition I having high cohesive force.

In addition, the upper limit of the mass average molecular weight of the (meth)acrylic polymer (A) is preferably 2,000,000 or less, more preferably 1,500,000 or less, and even more preferably 1,000,000 or less, from the viewpoint of obtaining the present adhesive composition I having high fluidity and stress relaxation.

<Ultraviolet Absorber (B)>

The present adhesive composition I contains an ultraviolet absorber (B), thereby reducing degradation of a coating-type polarization element due to light irradiation.

When photocuring the present adhesive composition I containing an ultraviolet absorber (B), it is preferably cured with light rays having a wavelength different from the absorption wavelength of the ultraviolet absorber (B).

Examples of the ultraviolet absorber (B) include a benzophenone-based ultraviolet absorber containing a benzophenone structure, a benzotriazole-based ultraviolet absorber containing a benzotriazole structure, a triazine-based ultraviolet absorber containing a triazine structure, a salicylate-based ultraviolet absorber containing a salicylate structure, and a cyanoacrylate-based ultraviolet absorber containing a cyanoacrylate structure. These ultraviolet absorbers may be used alone or in combination of two or more types thereof.

Examples of the benzophenone-based ultraviolet absorber include 2,4-dihydroxybenzophenone, 2-hydroxy-4-methoxybenzophenone, 2-hydroxy-4-octoxybenzophenone, 2-hydroxy-4-benzyloxybenzophenone, 2-hydroxy-4-methoxy-5-sulfoxybenzophenone, 2-hydroxy-4-methoxy-5-sulfoxytrihydridolate benzophenone, 2,2′-dihydroxy-4-methoxybenzophenone, 2,2′,4,4′-tetrahydroxybenzophenone, 2,2′-dihydroxy-4,4′-dimethoxybenzophenone, 2,2′-dihydroxy-4,4′-dimethoxy-5-sodium sulfoxybenzophenone, bis(5-benzoyl-4-hydroxy-2-methoxyphenyl)methane, 2-hydroxy-4-n-dodecyloxybenzophenone, and 2-hydroxy-4-methoxy-2′-carboxybenzophenone.

Examples of the benzotriazole-based ultraviolet absorber include 2-(2-hydroxy-5-methylphenyl)benzotriazole, 2-(2-hydroxy-5-tert-octylphenyl)benzotriazole, 2-(2-hydroxy-3,5-dicumylphenyl)phenylbenzotriazole, 2-(2-hydroxy-3-tert-butyl-5-methylphenyl)-5-chlorobenzotriazole, 2,2′-methylenebis[4-(1,1,3,3-tetramethylbutyl)-6-(2H-benzotriazol-2-yl)phenol], 2-(2-hydroxy-3,5-di-tert-butylphenyl)benzotriazole, 2-(2-hydroxy-3,5-di-tert-butylphenyl)-5-chlorobenzotriazole, 2-(2-hydroxy-3,5-di-tert-amylphenyl)benzotriazole, 2-(2-hydroxy-5-tert-octylphenyl)benzotriazole, 2-(2-hydroxy-5-tert-butylphenyl)benzotriazole, 2-(2-hydroxy-4-octoxyphenyl)benzotriazole, 2,2′-methylenebis(4-cumyl-6-benzotriazolephenyl), and 2-[2-hydroxy-3-(3,4,5,6-tetrahydrophthalimidomethyl)-5-methylphenyl]benzotriazole.

Examples of the triazine-based ultraviolet absorber include 2-(2-hydroxy-4-methoxyphenyl)-4,6-diphenyl-1,3,5-triazine, 2-(2-hydroxy-4-ethoxyphenyl)-4,6-diphenyl-1,3,5-triazine, 2-(2-hydroxy-4-propoxyphenyl)-4,6-diphenyl-1,3,5-triazine, 2-(2-hydroxy-4-butoxyphenyl)-4,6-diphenyl-1,3,5-triazine, 2-(2-hydroxy-4-hexyloxyphenyl)-4,6-diphenyl-1,3,5-triazine, 2-(2-hydroxy-4-octyloxyphenyl)-4,6-diphenyl-1,3,5-triazine, 2-(2-hydroxy-4-dodecyloxyphenyl)-4,6-diphenyl-1,3,5-triazine, 2-(2-hydroxy-4-benzyloxyphenyl)-4,6-diphenyl-1,3,5-triazine, 2,4-bis(2-hydroxy-4-butoxyphenyl)-6-(2,4-dibutoxyphenyl)-1,3-5-triazine, 2,4,6-tris(2-hydroxy-4-hexyloxy-3-methylphenyl)-1,3,5-triazine, 2-(2-hydroxy-4-[1-octyloxycarbonylethoxy]phenyl)-4,6-bis(4-phenylphenyl)-1,3,5-triazine, 2-[4-[(2-hydroxy-3-dodecyloxypropyl)oxy]-2-hydroxyphenyl]-4,6-bis(2,4-dimethylphenyl)-1,3,5-triazine, 2-[4-[(2-hydroxy-3-tridecyloxypropyl)oxy]-2-hydroxyphenyl]-4,6-bis(2,4-dimethylphenyl)-1,3,5-triazine, 2-[4-[(2-hydroxy-3-(2′-ethyl)hexyl)oxy]-2-hydroxyphenyl]-4,6-bis(2,4-dimethylphenyl)-1,3,5-triazine, 2,4-bis(2,4-dimethylphenyl)-6-[2-hydroxy-4-(3-octyloxy-2-hydroxypropyloxy)-5-α-cumylphenyl]-s-triazine, 2,4-bis(2,4-dimethylphenyl)-6-[2-hydroxy-4-(3-nonyloxy-2-hydroxypropyloxy)-5-α-cumylphenyl]-s-triazine, 2,4-bis(2,4-dimethylphenyl)-6-[2-hydroxy-4-(3-decyloxy-2-hydroxypropyloxy)-5-α-cumylphenyl]-s-triazine, and 2-(2-hydroxy-4-acryloyloxyethoxyphenyl)-4,6-bis(2,4-dimethylphenyl)-1,3,5-triazine.

Examples of the salicylate-based ultraviolet absorber include phenyl salicylate, p-tert-butylphenyl salicylate, and p-octylphenyl salicylate.

Examples of the cyanoacrylate-based ultraviolet absorber include 2-ethylhexyl-2-cyano-3,3′-diphenyl acrylate, and ethyl-2-cyano-3,3′-diphenyl acrylate.

Among them, benzophenone-based ultraviolet absorbers, benzotriazole-based ultraviolet absorbers, and triazine-based ultraviolet absorbers are preferred from the viewpoint of effectively suppressing light reaching a coating-type polarization element. Among them, benzophenone-based ultraviolet absorbers containing a benzophenone structure are more preferred from the viewpoint of excellent yellowing resistance.

Among them, dihydroxybenzophenone-based ultraviolet absorbers such as 2,4-dihydroxybenzophenone, 2,2′-dihydroxy-4-methoxybenzophenone, 2,2′,4,4′-tetrahydroxybenzophenone, 2,2′-dihydroxy-4,4′-dimethoxybenzophenone, and 2,2′-dihydroxy-4,4′-dimethoxy-5-sodium sulfoxybenzophenone are more preferred from the viewpoint of being able to block light rays up to a long wavelength region.

The lower limit of the content of the ultraviolet absorber (B) is preferably 0.1 part by mass or more, more preferably 0.5 part by mass or more, even more preferably 1.5 parts by mass or more, still more preferably 3 parts by mass or more, particularly preferably 5 parts by mass or more, and most preferably 6 parts by mass or more, relative to 100 parts by mass of the (meth)acrylic polymer (A), from the viewpoint of improving the light resistance reliability.

In addition, the upper limit of the content of the ultraviolet absorber (B) is preferably 15 parts by mass or less, more preferably 12 parts by mass or less, even more preferably 10 parts by mass or less, particularly preferably 8 parts by mass or less, and most preferably 7 parts by mass or less, relative to 100 parts by mass of the (meth)acrylic polymer (A), from the viewpoint of suppressing bleeding out and improving the yellowing resistance.

<Radical Polymerization Initiator (C)>

The radical polymerization initiator (C) may be capable of releasing a substance that initiates radical polymerization by at least one of heat and irradiation with active energy rays such as light. In particular, photoradical polymerization initiators capable of initiating a reaction by irradiation with active energy rays such as light are preferred because they do not require aging during curing and are excellent in productivity.

Examples of the thermal radical polymerization initiators include organic peroxides such as hydrogen peroxide and perbenzoic acid, and azo compounds such as azobisbutyronitrile.

The photoradical polymerization initiators can be roughly classified into two types in terms of the radical generation mechanism: a photocleavage-type radical polymerization initiator capable of generating radicals by cleaving and decomposing a single bond of the photoradical polymerization initiator itself; and a hydrogen abstraction-type photoradical polymerization initiator capable of forming an excited complex by the photoexcited initiator and a hydrogen donor in the system, and transferring hydrogen in the hydrogen donor.

Of these, the photocleavage-type radical polymerization initiator is decomposed and converted into another compound in radical generation by light irradiation, and, if once excited, it has no function as a reaction initiator. For this reason, the photocleavage-type radical polymerization initiator is preferred because it does not remain as an active species in an adhesive layer or adhesive sheet after the crosslinking reaction is completed, and there is no possibility of the adhesive layer or adhesive sheet being unexpectedly deteriorated by light.

On the other hand, the hydrogen abstraction-type photoradical polymerization initiator is useful because it retains its function as a reaction initiator even after being irradiated with light multiple times, and it does not generate decomposition products, such as those generated by the photocleavage-type radical polymerization initiator, during the radical generation reaction by irradiation with active energy rays such as ultraviolet rays, so that it is less likely to become a volatile component after the reaction is completed and damage to adherends can be reduced.

Among the photoradical polymerization initiators, it is preferred to select a photocleavage-type radical polymerization initiator in the present adhesive composition I from the viewpoint of ensuring the light resistance reliability of the adhesive layer or adhesive sheet.

When using a photoradical polymerization initiator, from the viewpoint of avoiding reaction inhibition by the ultraviolet absorber (B), it is preferred to use a visible light initiator that generates radicals by irradiation with visible light such as light rays having wavelengths of at least 390 nm, 405 nm, and 410 nm, for example, light rays in a wavelength range of 380 nm to 700 nm, to serve as a starting point for the crosslinking reaction of the present adhesive composition I.

The visible light initiator may generate radicals only by irradiation with visible light, or may generate radicals by irradiation with light rays in a wavelength range other than the visible light range.

Examples of the photocleavage-type radical polymerization initiator include 2,2-dimethoxy-1,2-diphenylethan-1-one, 1-hydroxycyclohexyl phenyl ketone, 2-hydroxy-2-methyl-1-phenyl-propan-1-one, 1-(4-(2-hydroxyethoxy)phenyl)-2-hydroxy-2-methyl-1-propan-1-one, 2-hydroxy-1-[4-{4-(2-hydroxy-2-methyl-propionyl)benzyl}phenyl]-2-methyl-propan-1-one, oligo(2-hydroxy-2-methyl-1-(4-(1-methylvinyl)phenyl)propanone), methyl phenylglyoxylate, 2-benzyl-2-dimethylamino-1-(4-morpholinophenyl)butan-1-one, 2-methyl-1-[4-(methylthio)phenyl]-2-morpholinopropan-1-one, 2-(dimethylamino)-2-[(4-methylphenyl)methyl]-1-[4-(4-morpholinyl)phenyl]-1-butanone, bis(2,4,6-trimethylbenzoyl)-phenylphosphine oxide, 2,4,6-trimethylbenzoyldiphenylphosphine oxide, (2,4,6-trimethylbenzoyl)ethoxyphenylphosphine oxide, and derivatives thereof.

Among them, from the viewpoint of becoming a decomposed product after the reaction to be discolored, acylphosphine oxide-based photoinitiators such as bis(2,4,6-trimethylbenzoyl)-phenylphosphine oxide, 2,4,6-trimethylbenzoyldiphenylphosphine oxide, (2,4,6-trimethylbenzoyl)ethoxyphenylphosphine oxide, and bis(2,6-dimethoxybenzoyl)2,4,4-trimethylpentylphosphine oxide are preferred.

Examples of the hydrogen abstraction-type photoradical polymerization initiator include bis(2-phenyl-2-oxoacetic acid)oxybisethylene, phenylglyoxylic acid methyl ester, a mixture of oxy-phenyl-acetic acid 2-[2-oxo-2-phenyl-acetoxy-ethoxy]ethyl ester and oxy-phenyl-acetic acid 2-[2-hydroxy-ethoxy]ethyl ester, thioxanthone, 2-chlorothioxanthone, 3-methylthioxanthone, 2,4-dimethylthioxanthone, anthraquinone, 2-methylanthraquinone, 2-ethylanthraquinone, 2-tert-butylanthraquinone, 2-aminoanthraquinone, camphorquinone, and derivatives thereof.

Among them, it is preferred to be any one or two selected from the group consisting of phenylglyoxylic acid methyl ester and a mixture of oxy-phenyl-acetic acid 2-[2-oxo-2-phenyl-acetoxy-ethoxy]ethyl ester and oxy-phenyl-acetic acid 2-[2-hydroxy-ethoxy]ethyl ester.

The photoradical polymerization initiator is not limited to the substances listed above. Any one of the photoradical polymerization initiators listed above or a derivative thereof may be used, or two or more types thereof may be used in combination. Also, a visible light initiator may be mixed with an initiator that generates radicals only by irradiation with other light rays such as ultraviolet rays.

A thermal radical polymerization initiator and a photoradical polymerization initiator may be used simultaneously.

Although the content of the radical polymerization initiator (C) is not particularly limited, it is preferably 0.1 part by mass or more, more preferably 0.5 part by mass or more, even more preferably 1 part by mass or more, and particularly preferably 2 parts by mass or more, relative to 100 parts by mass of the (meth)acrylic polymer (A), from the viewpoint of sufficiently advancing the polymerization reaction and improving the shape stability of the adhesive sheet.

In addition, the upper limit of the content of the radical polymerization initiator (C) is preferably 15 parts by mass or less, more preferably 10 parts by mass or less, even more preferably 6 parts by mass or less, and particularly preferably 4 parts by mass or less, relative to 100 parts by mass of the (meth)acrylic polymer (A), from the viewpoint of ensuring the adhesiveness.

<Polyfunctional (Meth)Acrylate (D)>

The present adhesive composition I preferably contains a polyfunctional (meth)acrylate (D) as necessary.

The inclusion of the polyfunctional (meth)acrylate (D) in the present adhesive composition I allows the present adhesive composition I to form a crosslinked structure and to impart cohesive force and sufficient toughness to the present adhesive sheet I. This configuration allows, when preparing a coating-type polarization element with an adhesive layer described below, to prevent the surface of the coating-type polarization element from being waved and the adhesive layer from being deformed and cracked during cutting.

The polyfunctional (meth)acrylate (D) is a compound or composition that forms a crosslinked structure in the present adhesive composition I, and examples thereof include (meth)acrylic monomers and (meth)acrylic oligomers having two or more functional groups.

Examples of the (meth)acrylic monomers include 1,4-butanediol di(meth)acrylate, glycerin di(meth)acrylate, neopentyl glycol di(meth)acrylate, glycerin glycidyl ether di(meth)acrylate, 1,6-hexanediol di(meth)acrylate, 1,9-nonanediol di(meth)acrylate, tricyclodecane dimethacrylate, tricyclodecanedimethanol di(meth)acrylate, bisphenol A polyethoxy di(meth)acrylate, bisphenol A polypropoxy di(meth)acrylate, bisphenol F polyethoxy di(meth)acrylate, ethylene glycol di(meth)acrylate, neopentyl glycol di(meth)acrylate, trimethylolpropane trioxyethyl (meth)acrylate, ε-caprolactone-modified tris(2-hydroxyethyl)isocyanurate tri(meth)acrylate, pentaerythritol tri(meth)acrylate, propoxylated pentaerythritol tri(meth)acrylate, ethoxylated pentaerythritol tri(meth)acrylate, pentaerythritol tetra(meth)acrylate, propoxylated pentaerythritol tetra(meth)acrylate, ethoxylated pentaerythritol tetra(meth)acrylate, dipentaerythritol hexa(meth)acrylate, polyethylene glycol di(meth)acrylate, polypropylene glycol di(meth)acrylate, polytetramethylene glycol di(meth)acrylate, tris(acryloxyethyl)isocyanurate, dipentaerythritol hexa(meth)acrylate, dipentaerythritol penta(meth)acrylate, tripentaerythritol hexa(meth)acrylate, tripentaerythritol penta(meth)acrylate, hydroxypivalic acid neopentyl glycol di(meth)acrylate, di(meth)acrylate of ε-caprolactone adduct of hydroxypivalic acid neopentyl glycol, trimethylolpropane tri(meth)acrylate, trimethylolpropane polyethoxy tri(meth)acrylate, and ditrimethylolpropane tetra(meth)acrylate.

Among them, (meth)acrylic monomers are preferred from the viewpoint of imparting sufficient toughness to the cured product, and among them, polyfunctional (meth)acrylic monomers having an alkylene glycol skeleton such as polyethylene glycol di(meth)acrylate, polypropylene glycol di(meth)acrylate, and polytetramethylene glycol di(meth)acrylate are more preferred.

The molecular weight of the (meth)acrylic monomer is preferably 200 or more, more preferably 300 or more, even more preferably 400 or more, and particularly preferably 500 or more, from the viewpoint of imparting sufficient flexibility to the cured product. In addition, the upper limit of the molecular weight is usually 3,000 or less, and preferably 2,000 or less.

Examples of the (meth)acrylic oligomers include polyfunctional (meth)acrylic oligomers such as polyester (meth)acrylate, epoxy (meth)acrylate, urethane (meth)acrylate, and polyether (meth)acrylate.

Among them, urethane (meth)acrylate oligomers are preferred from the viewpoint of imparting sufficient toughness to the cured product.

From the viewpoint of being able to obtain a cured product having high toughness, in other words, a cured product having sufficient flexibility when curing the present adhesive composition I, the polyfunctional (meth)acrylate (D) is preferably a (meth)acrylic oligomer having a molecular weight of 3,000 or more, and is more preferably a polyfunctional (meth)acrylate having a molecular weight of 5,000 or more, even more preferably 8,000 or more, and still more preferably 10,000 or more. In addition, the upper limit of the molecular weight is usually 100,000 or less, and preferably 50,000 or less.

The content mass of the polyfunctional (meth)acrylate (D) is preferably 1 part by mass or more, more preferably 2 parts by mass or more, even more preferably 5 parts by mass or more, and particularly preferably 10 parts by mass or more, relative to 100 parts by mass of the (meth)acrylic polymer (A), from the viewpoint of imparting the shape stability of the adhesive sheet and the durability when forming a laminate from the adhesive sheet.

The upper limit of the content mass of the polyfunctional (meth)acrylate (D) is preferably 100 parts by mass or less, more preferably 60 parts by mass or less, even more preferably 40 parts by mass or less, and particularly preferably 30 parts by mass or less, relative to 100 parts by mass of the (meth)acrylic polymer (A), from the viewpoint of ensuring the adhesiveness.

<Other Components>

The present adhesive composition I may optionally contain various additives such as a tackifier resin, an antioxidant, a photostabilizer, a metal deactivator, an anti-aging agent, a moisture absorbent, a rust inhibitor, a silane coupling agent, and inorganic particles, as “other components”.

Moreover, a reaction catalyst such as a tertiary amine compound, a quaternary ammonium compound, or a tin laurate compound may be appropriately contained as necessary.

<Curability>

The present adhesive composition I may be cured in one stage, or may be cured in multiple stages.

In other words, it can be cured by leaving room for further curing. In terms of gel fraction, the present adhesive composition I may be cured with a gel fraction of 60% or more in one cure, or may be cured with a gel fraction of 20% to 60% in the first cure by leaving room for further curing.

For example, when the present adhesive composition I has active energy ray curability, the present adhesive composition I is laminated with an image display device constituting member such as a coating-type polarization element, or with a coating-type polarization element and other image display device constituting members to form a laminate, and the laminate can then be irradiated with light to cure the present adhesive composition I, so that the coating-type polarization element and the other image display device constituting members adhere more firmly to improve the reliability of the laminate.

Ultraviolet light and visible light are suitable light sources for light irradiation from the viewpoint of suppressing damage to image display device constituting members and controlling the reaction.

Although the irradiation time and the irradiation method are not particularly limited, it is preferred to irradiate light from the opposite side of the laminated surface of the image display device constituting member such as the coating-type polarization element.

The irradiation energy, the irradiation time, and the irradiation method of the active energy rays are not particularly limited as long as the (meth)acrylate component can be polymerized by activating the initiator.

<Light Transmittance>

From the viewpoint of preventing photodegradation of a coating-type polarization element used in combination with an adhesive layer formed from the present adhesive composition I, the present adhesive composition I preferably has a transmittance at a wavelength of 400 nm of an adhesive layer having a thickness of 50 μm formed from the present adhesive composition I of 50% or less, more preferably 40% or less, even more preferably 30% or less, and particularly preferably 25% or less.

Also, from the viewpoint of preventing photodegradation of a coating-type polarization element used in combination with an adhesive layer formed from the present adhesive composition I, the present adhesive composition I preferably has a transmittance at a wavelength of 380 nm of an adhesive layer having a thickness of 50 μm formed from the present adhesive composition I of less than 20%, more preferably 5% or less, even more preferably 2% or less, and particularly preferably 1% or less.

Furthermore, from the viewpoint of ensuring sufficient image visibility in an image display device using an adhesive layer formed from the present adhesive composition I, the present adhesive composition I preferably has a transmittance at a wavelength of 430 nm of an adhesive layer having a thickness of 50 μm formed from the present adhesive composition I of 50% or more, more preferably 60% or more, even more preferably 70% or more, particularly preferably 80% or more, and most preferably 85% or more.

<<Present Adhesive Sheet I>>

An adhesive sheet I for coating-type polarization elements (referred to as “present adhesive sheet I”) according to an example of the embodiment of the present invention is an adhesive sheet including an adhesive layer I (referred to as “present adhesive layer I”) formed using the present adhesive composition I.

The present adhesive sheet I may have a single-layer structure composed of an adhesive layer formed using the present adhesive composition I, or a multilayer structure of two or more layers including the adhesive layer and other layers.

When the present adhesive sheet I has a multilayer structure of two or more layers, the composition of the layers other than the layer composed of the present adhesive composition I is arbitrary. However, when, for example, the intermediate layer, the outermost layer, or the backmost layer is formed of a layer other than the present adhesive layer I, from the viewpoint of further increasing the interlayer adhesion, the adhesive composition forming a layer other than the present adhesive layer I is also preferably formed from an adhesive composition containing a (meth)acrylic polymer as a main component resin, and it is more preferred to contain the same (meth)acrylic polymer (A) as in the present adhesive layer I as a main component resin. Furthermore, it is more preferred that layers other than the present adhesive layer I also contain a polyfunctional (meth)acrylate and a radical polymerization initiator.

When the present adhesive sheet I has a multilayer structure of two or more layers, it is preferred that at least the outermost layer, the backmost layer, or both layers are layers corresponding to the present adhesive layer. All the layers may be layers corresponding to the present adhesive layer.

When the present adhesive sheet I has a multilayer structure of two or more layers, the thickness of the layer corresponding to the present adhesive layer preferably occupies 10% or more and 100% or less of the total thickness of the present adhesive sheet I, more preferably 14% or more or 70% or less, and even more preferably 20% or more or 50% or less.

(Light Transmittance)

From the viewpoint of preventing photodegradation of a coating-type polarization element used in combination with the present adhesive layer I or the present adhesive sheet I, the present adhesive layer I or the present adhesive sheet I preferably has a light transmittance at a wavelength of 400 nm of 50% or less, more preferably 40% or less, even more preferably 30% or less, and particularly preferably 25% or less.

Also, from the viewpoint of preventing photodegradation of a coating-type polarization element used in combination with the present adhesive layer I or the present adhesive sheet I, the present adhesive layer I or the present adhesive sheet I preferably has a light transmittance at a wavelength of 380 nm of less than 20%, more preferably 5% or less, even more preferably 2% or less, and particularly preferably 1% or less.

Furthermore, from the viewpoint of ensuring sufficient image visibility in an image display device using the present adhesive layer I or the present adhesive sheet I, the present adhesive layer I or the present adhesive sheet I preferably has a light transmittance at a wavelength of 430 nm of 50% or more, more preferably 60% or more, even more preferably 70% or more, particularly preferably 80% or more, and most preferably 85% or more.

(b* Value)

From the viewpoint of suppressing adverse effects on image quality in an image display device using the present adhesive layer I or the present adhesive sheet I, the present adhesive layer I or the present adhesive sheet I preferably has a b* value of 10 or less, more preferably 5 or less, even more preferably 3 or less, and particularly preferably 2 or less.

The b* value is the value of b* in the color space of L*a*b* display defined by Japanese Industrial Standards (JIS) Z 8781-4, which means that the yellowish tint increases as the value increases on the positive side, the blueish tint increases as the value increases on the negative side, and the color becomes achromatic as the value approaches 0 (zero).

In order to adjust the light transmittance at wavelengths of 380 nm, 400 nm, and 430 nm and the b* value in the above ranges in the present adhesive layer I or the present adhesive sheet I, it is preferred to adjust the type and amount of the ultraviolet absorber accordingly. However, it is not limited to this method.

It is also preferred for the present adhesive layer I or the present adhesive sheet I to satisfy the relationship of the following formulae (I) and (II) for the light transmittance T(380) at a wavelength of 380 nm, the light transmittance T(430) at a wavelength of 430 nm, and the b* value:

0≤T(380)×b*≤50 (I); and

70≤T(430)×b*≤220 (II).

When the present adhesive layer I or the present adhesive sheet I satisfies the relationship of the formulae (I) and (II), both the prevention of photodegradation of a coating-type polarization element and the image visibility of an image display device can be achieved at a higher level.

From such a viewpoint, the value of T(380)×b* in the formula (I) is preferably 0 to 50, more preferably 0 to 40, even more preferably 0 to 30, and particularly preferably 0 to 20.

The value of T(430)×b* in the formula (II) is preferably 70 to 220, more preferably 80 or more or 210 or less, even more preferably 90 or more or 200 or less, and particularly preferably 100 or more or 190 or less.

(Gel Fraction)

The present adhesive layer I or the present adhesive sheet I preferably has a gel fraction of 20% or more when used for adhesion. When the gel fraction is 20% or more, the shape stability of the adhesive sheet and the durability when made into a laminate can be imparted.

From such a viewpoint, the gel fraction of the present adhesive layer I or the present adhesive sheet I is more preferably 40% or more, even more preferably 50% or more, and particularly preferably 60% or more.

In addition, when the gel fraction is 95% or less, even if the adherend is a member having a step portion on the surface, the adhesive sheet can be filled in every corner by following the step without causing distortion or deformation of the member. From such a viewpoint, the gel fraction of the present adhesive layer I or the present adhesive sheet I is preferably 95% or less, more preferably 85% or less, even more preferably 80% or less, and particularly preferably 75% or less.

In order to adjust the gel fraction in the above range when the present adhesive layer I or the present adhesive sheet I is used for adhesion, it is preferred to adjust the composition and the molecular weight of the (meth)acrylic polymer (A), to adjust the amounts of the added polyfunctional (meth)acrylate (D) and the radical polymerization initiator (C), or to adjust the intensity and the integrated light amount of the active energy rays to be irradiated. However, it is not limited to these methods.

(Thickness)

The present adhesive layer I or the present adhesive sheet I preferably has a thickness of 10 μm or more, more preferably 20 μm or more, even more preferably 30 μm or more, and particularly preferably 40 μm or more, from the viewpoint of protecting a coating-type polarization element. In addition, the upper limit of the thickness is preferably 175 μm or less, more preferably 120 μm or less, even more preferably 80 μm or less, and particularly preferably 60 μm or less, from the viewpoint of contributing to thinning of an image display device.

<Method for Producing Present Adhesive Sheet I>

Next, a method for producing the present adhesive sheet I will be described. However, the following description is an example of a method for producing the present adhesive sheet I, and the present adhesive sheet I is not limited to that produced by such a method.

The present adhesive sheet I may be produced by mixing a (meta)acrylic polymer (A), an ultraviolet absorber (B), a radical polymerization initiator (C), optionally a polyfunctional (meth)acrylate (D), and optionally “other components” in predetermined amounts to prepare the present adhesive composition I, forming the present adhesive composition I into a sheet shape, and crosslinking, i.e. polymerizing the curable compound, as necessary, for curing. However, it is not limited to this method.

In preparing the present adhesive composition I, the raw materials may be kneaded using a temperature-controlled kneader (such as a uniaxial extruder, a biaxial extruder, a planetary mixer, a biaxial mixer, or a pressure kneader).

In mixing the various raw materials, the various additives may be blended with the resin in advance and then fed to the kneader; or all the materials are melt-mixed in advance and then fed to the kneader; or a master batch in which only the additives are concentrated in the resin in advance may be prepared and then fed to the kneader.

Examples of the method for forming the present adhesive composition I into a sheet shape include known methods such as a wet laminating method, a dry laminating method, an extrusion casting method using a T-die, an extrusion laminating method, a calendering method, an inflation method, an injection molding method, and a liquid injection curing method. Among them, a wet laminating method, an extrusion casting method, and an extrusion laminating method are preferred for preparing a sheet.

When the present adhesive composition I contains a radical polymerization initiator (C), a cured product can be produced by irradiating the composition with heat and/or active energy rays for curing. In particular, the present adhesive sheet I can be produced by irradiating a molded body such as a sheet body of the present adhesive composition I with heat and/or active energy rays.

Examples of the active energy rays to be irradiated include ionizing rays such as α-rays, β-rays, γ-rays, neutron rays, and electron rays; ultraviolet light; and visible light. Among them, ultraviolet light and visible light are preferred from the viewpoint of suppressing damage to optical device constituting members and controlling the reaction.

The irradiation energy, the irradiation time, and the irradiation method of the active energy rays are not particularly limited as long as the (meth)acrylate component can be polymerized by activating the initiator.

As another embodiment of the method for producing the present adhesive sheet I, the present adhesive composition I can be dissolved in a suitable solvent, and various coating methods may be used.

In the case of using the coating methods, the present adhesive sheet I can also be obtained by heat curing in addition to the above-mentioned active energy ray irradiation curing.

In the case of using the coating methods, the thickness of the present adhesive sheet I can be adjusted by the coating thickness and the solid content concentration of the coating liquid.

<<Present Adhesive Composition II>>

An adhesive sheet II for image display device constituting members (referred to as “present adhesive sheet II”) according to an example of the embodiment of the present invention is an adhesive sheet formed from an adhesive composition II (referred to as “present adhesive composition II”) containing a (meta)acrylic polymer (A), a hydroxy group-containing benzophenone compound (B1), and a radical polymerization initiator (C).

Examples of the “image display device constituting members” in the adhesive sheet II for image display device constituting members include a reflective sheet, a light guide plate and a light source, a diffusion film, a prism sheet, a liquid crystal panel, a retardation plate, a glass substrate, a polarization plate, an organic EL panel, an electrode, an anti-reflection film, a color filter, a touch sensor, a cover glass, and a cover plastic; or an integrally combined product composed of two or more of these members. However, it is not limited to these members.

The present adhesive composition II may be cured by heat or by active energy rays, as described below. In particular, those that are cured by active energy rays are preferred because they do not require aging and are excellent in productivity.

The present adhesive composition II may be cured in multiple stages, as described below.

It is usually difficult to adopt an active energy ray curing system for an adhesive sheet containing an ultraviolet absorber, because when the sheet is cured by active energy rays, the ultraviolet absorber interferes with the curing by the active energy rays. However, when it is daringly applied in the present invention, a good adhesive sheet can be obtained.

<(Meth)Acrylic Polymer (A)>

For the (meth)acrylic polymer (A) of the present adhesive composition II and its content, the above description in the (meth)acrylic polymer (A) of the present adhesive composition I applies. In this case, the above description applies by replacing the present adhesive composition I with the present adhesive composition II.

<Hydroxy Group-Containing Benzophenone Compound (B1)>

The present adhesive composition II contains a hydroxy group-containing benzophenone compound (B1) as an ultraviolet absorber, thereby reducing degradation of an image display device constituting member due to light irradiation while ensuring the light resistance reliability of the adhesive sheet itself.

When photocuring the present adhesive composition II containing a hydroxy group-containing benzophenone compound (B1), it is preferably cured with light rays having a wavelength different from the absorption wavelength of the hydroxy group-containing benzophenone compound (B1) having ultraviolet absorption properties.

Examples of the hydroxy group-containing benzophenone compound (B1) include 2,4-dihydroxybenzophenone, 2-hydroxy-4-methoxybenzophenone, 2-hydroxy-4-octoxybenzophenone, 2-hydroxy-4-benzyloxybenzophenone, 2-hydroxy-4-methoxy-5-sulfoxybenzophenone, 2-hydroxy-4-methoxy-5-sulfoxytrihydridolate benzophenone, 2,2′-dihydroxy-4-methoxybenzophenone, 2,2′,4,4′-tetrahydroxybenzophenone, 2,2′-dihydroxy-4,4′-dimethoxybenzophenone, 2,2′-dihydroxy-4,4′-dimethoxy-5-sodium sulfoxybenzophenone, bis(5-benzoyl-4-hydroxy-2-methoxyphenyl)methane, 2-hydroxy-4-n-dodecyloxybenzophenone, and 2-hydroxy-4-methoxy-2′-carboxybenzophenone.

Among them, dihydroxybenzophenone compounds such as 2,4-dihydroxybenzophenone, 2,2′-dihydroxy-4-methoxybenzophenone, 2,2′,4,4′-tetrahydroxybenzophenone, 2,2′-dihydroxy-4,4′-dimethoxybenzophenone, and 2,2′-dihydroxy-4,4′-dimethoxy-5-sodium sulfoxybenzophenone are more preferred from the viewpoint of being able to block light rays up to a long wavelength region.

The lower limit of the content of the hydroxy group-containing benzophenone compound (B1) is preferably 0.1 part by mass or more, more preferably 0.5 part by mass or more, even more preferably 1.5 parts by mass or more, still more preferably 3 parts by mass or more, particularly preferably 5 parts by mass or more, and most preferably 6 parts by mass or more, relative to 100 parts by mass of the (meth)acrylic polymer (A), from the viewpoint of improving the light resistance reliability.

In addition, the upper limit of the content of the hydroxy group-containing benzophenone compound (B1) is preferably 15 parts by mass or less, more preferably 12 parts by mass or less, even more preferably 10 parts by mass or less, particularly preferably 8 parts by mass or less, and most preferably 7 parts by mass or less, relative to 100 parts by mass of the (meth)acrylic polymer (A), from the viewpoint of suppressing bleeding out and improving the yellowing resistance.

<Radical Polymerization Initiator (C)>

For the radical polymerization initiator (C) of the present adhesive composition II and its content, the above description in the radical polymerization initiator (C) of the present adhesive composition I applies. In this case, the above description applies by replacing the present adhesive composition I with the present adhesive composition II, and the ultraviolet absorber (B) with the hydroxy group-containing benzophenone compound (B1).

The radical polymerization initiator (C) of the present adhesive composition II preferably has an absorption maximum at a wavelength of at least 400 nm to 430 nm from the viewpoint of suppressing the coloring of the present adhesive sheet II due to the radical polymerization initiator (C) itself while avoiding reaction inhibition by the hydroxy group-containing benzophenone compound (B1).

The term “absorption maximum” means a wavelength of maximum absorbance in the absorption spectrum.

In addition, from the viewpoint of ensuring the performance balance between light resistance reliability and shape stability of the present adhesive sheet II itself, the content mass ratio of the hydroxy group-containing benzophenone compound (B1) to the radical polymerization initiator (C) is preferably 1:0.05 to 1:20, more preferably 1:0.1 to 1:10, and even more preferably 1:0.3 to 1:2 ((B1):(C)).

<Polyfunctional (Meth)Acrylate (D)>

The present adhesive composition II preferably contains a polyfunctional (meth)acrylate (D) as necessary. The inclusion of the polyfunctional (meth)acrylate (D) in the present adhesive composition II allows the present adhesive composition II to form a crosslinked structure and to impart cohesive force and sufficient toughness to the present adhesive sheet II. The sufficient toughness of the present adhesive sheet II allows, when preparing an image display device constituting member with an adhesive layer described below, to prevent the surface of the image display device constituting member from being waved and the adhesive layer from being deformed and cracked during cutting.

For the polyfunctional (meth)acrylate (D) of the present adhesive composition II and its content, the above description in the polyfunctional (meth)acrylate (D) of the present adhesive composition I applies. In this case, the above description applies by replacing the present adhesive composition I with the present adhesive composition II.

<Other Components>

The present adhesive composition II may optionally contain various additives such as a tackifier resin, an antioxidant, a photostabilizer, a metal deactivator, an anti-aging agent, a moisture absorbent, a rust inhibitor, a silane coupling agent, and inorganic particles, as “other components”.

Moreover, a reaction catalyst such as a tertiary amine compound, a quaternary ammonium compound, or a tin laurate compound may be appropriately contained as necessary.

<Curability>

For the curability of the present adhesive composition II, the above description in the curability of the present adhesive composition I applies. In this case, the above description applies by replacing the present adhesive composition I with the present adhesive composition II.

<Light Transmittance>

From the viewpoint of preventing photodegradation of an image display device constituting member used in combination with an adhesive layer formed from the present adhesive composition II, the present adhesive composition II preferably has a transmittance at a wavelength of 400 nm of an adhesive layer having a thickness of 50 μm formed from the present adhesive composition II of less than 30%, more preferably 25% or less, even more preferably 22% or less, and particularly preferably 20% or less.

Also, from the viewpoint of preventing photodegradation of an image display device constituting member used in combination with an adhesive layer formed from the present adhesive composition II, the present adhesive composition II preferably has a transmittance at a wavelength of 380 nm of an adhesive layer having a thickness of 50 μm formed from the present adhesive composition II of less than 20%, more preferably 5% or less, even more preferably 2% or less, and particularly preferably 1% or less.

Furthermore, from the viewpoint of ensuring sufficient image visibility in an image display device using an adhesive layer formed from the present adhesive composition II, the present adhesive composition II preferably has a transmittance at a wavelength of 430 nm of an adhesive layer having a thickness of 50 μm formed from the present adhesive composition II of 50% or more, more preferably 60% or more, even more preferably 70% or more, particularly preferably 80% or more, and most preferably 85% or more.

<<Present Adhesive Sheet II>>

An adhesive sheet II for image display device constituting members (referred to as “present adhesive sheet II”) according to an example of the embodiment of the present invention is an adhesive sheet including an adhesive layer II (referred to as “present adhesive layer II”) formed using the present adhesive composition II.

The present adhesive sheet II may have a single-layer structure composed of an adhesive layer formed using the present adhesive composition II, or a multilayer structure of two or more layers including the adhesive layer and other layers.

When the present adhesive sheet II has a multilayer structure of two or more layers, the composition of the layers other than the layer composed of the present adhesive composition II is arbitrary. However, when, for example, the intermediate layer, the outermost layer, or the backmost layer is formed of a layer other than the present adhesive layer II, from the viewpoint of further increasing the interlayer adhesion, the adhesive composition forming a layer other than the present adhesive layer II is also preferably formed from an adhesive composition containing a (meth)acrylic polymer as a main component resin, and it is more preferred to contain the same (meth)acrylic polymer (A) as in the present adhesive layer II as a main component resin. Furthermore, it is more preferred that layers other than the present adhesive layer II also contain a polyfunctional (meth)acrylate and a radical polymerization initiator.

When the present adhesive sheet II has a multilayer structure of two or more layers, it is preferred that at least the outermost layer, the backmost layer, or both layers are layers corresponding to the present adhesive layer. All the layers may be layers corresponding to the present adhesive layer II.

When the present adhesive sheet II has a multilayer structure of two or more layers, the thickness of the layer corresponding to the present adhesive layer II preferably occupies 10% or more and 100% or less of the total thickness of the present adhesive sheet, more preferably 14% or more or 70% or less, and even more preferably 20% or more or 50% or less.

(Light Transmittance)

From the viewpoint of preventing photodegradation of an image display device constituting member used in combination with the present adhesive layer II or the present adhesive sheet II, the present adhesive layer II or the present adhesive sheet II preferably has a transmittance at a wavelength of 400 nm of less than 30%, more preferably 25% or less, even more preferably 22% or less, and particularly preferably 20% or less.

Also, from the viewpoint of preventing photodegradation of an image display device constituting member used in combination with the present adhesive layer II or the present adhesive sheet II, the present adhesive layer II or the present adhesive sheet II preferably has a transmittance at a wavelength of 380 nm of less than 20%, more preferably 5% or less, even more preferably 2% or less, and particularly preferably 1% or less.

Furthermore, from the viewpoint of ensuring sufficient image visibility in an image display device using the present adhesive layer II or the present adhesive sheet II, the present adhesive layer II or the present adhesive sheet II preferably has a light transmittance at a wavelength of 430 nm of 50% or more, more preferably 60% or more, even more preferably 70% or more, particularly preferably 80% or more, and most preferably 85% or more.

(b* Value)

From the viewpoint of suppressing adverse effects on image quality in an image display device using the present adhesive layer II or the present adhesive sheet II, the present adhesive layer II or the present adhesive sheet II preferably has a b* value of 3.0 or less, more preferably 2.5 or less, even more preferably 2.0 or less, and particularly preferably 1.8 or less.

The b* value is the value of b* in the color space of L*a*b* display defined by JIS Z 8781-4, which means that the yellowish tint increases as the value increases on the positive side, the blueish tint increases as the value increases on the negative side, and the color becomes achromatic as the value approaches 0 (zero).

It is also preferred for the present adhesive layer II or the present adhesive sheet II to satisfy the relationship of the following formulae (I) and (II) for the light transmittance T(380) at a wavelength of 380 nm, the light transmittance T(430) at a wavelength of 430 nm, and the b* value:

0≤T(380)×b*≤50 (I); and

70≤T(430)×b*≤220 (II).

When the present adhesive layer II or the present adhesive sheet II satisfies the relationship of the formulae (I) and (II), both the prevention of photodegradation of an image display device constituting member and the image visibility of an image display device can be achieved at a higher level.

From such a viewpoint, the value of T(380)×b* in the formula (I) is preferably 0 to 50, more preferably 0 to 40, even more preferably 0 to 30, and particularly preferably 0 to 20.

The value of T(430)×b* in the formula (II) is preferably 70 to 220, more preferably 80 or more or 210 or less, even more preferably 90 or more or 200 or less, and particularly preferably 100 or more or 190 or less.

In order to adjust the light transmittance at wavelengths of 380 nm, 400 nm, and 430 nm and the b* value in the above ranges in the present adhesive layer II or the present adhesive sheet II, it is preferred to adjust the type and amount of the hydroxy group-containing benzophenone compound (B1) accordingly. However, it is not limited to this method.

(Gel Fraction)

For the gel fraction of the present adhesive layer II or the present adhesive sheet II, the above description in the gel fraction of the present adhesive layer I or the present adhesive sheet I applies. In this case, the above description applies by replacing the present adhesive layer I or the present adhesive sheet I with the present adhesive layer II or the present adhesive sheet II.

(Thickness)

For the thickness of the present adhesive layer II or the present adhesive sheet II, the above description in the thickness of the present adhesive layer I or the present adhesive sheet I applies. In this case, the above description applies by replacing the present adhesive layer I or the present adhesive sheet I with the present adhesive layer II or the present adhesive sheet II, and the coating-type polarization element with the image display device constituting member.

<Method for Producing Present Adhesive Sheet II>

For the method for producing the present adhesive sheet II, the above description in the method for producing the present adhesive sheet I applies. In this case, the above description applies by replacing the present adhesive composition I with the present adhesive composition II, the present adhesive sheet I with the present adhesive sheet II, the coating-type polarization element with the image display device constituting member, and the ultraviolet absorber (B) with the hydroxy group-containing benzophenone compound (B1).

<<Present Adhesive Sheet with Mold Release Films>>

The present adhesive sheets I and II each can also be formed into an adhesive sheet with mold release films (referred to as “present adhesive sheet with mold release films”) having a structure in which the present adhesive sheet I or II and mold release films are laminated.

For example, a single or multilayer sheet-shaped adhesive layer containing a layer composed of the present adhesive composition I or II can be formed on mold release films to obtain the present adhesive sheet with mold release films (see FIG. 6).

Known mold release films can be used as the materials for such mold release films.

As the materials for the mold release films, for example, those obtained by coating a silicone resin on a film such as a polyester film, a polyolefin film, a polycarbonate film, a polystyrene film, an acrylic film, a triacetyl cellulose film, or a fluororesin film for mold release treatment, and mold release papers can be appropriately selected and used.

The films may have other layers such as an antistatic layer, a hard coat layer, and an anchor layer as necessary.

In the case where the mold release films are laminated on both sides of the present adhesive sheet I or II, one mold release film may have the same laminate configuration or material as that of the other mold release film, or may have a different laminate configuration or material therefrom.

In addition, the thickness may be the same, or may be different.

Mold release films having different release forces or thicknesses can be laminated on both sides of the present adhesive sheet I or II.

The thickness of the mold release films is not particularly limited. From the viewpoint of processability and handleability, the thickness is preferably 12 μm to 250 μm, more preferably 25 μm or more or 200 μm or less, and even more preferably 38 μm or more or 188 μm or less.

The present adhesive sheets I and II can be formed, for example, by directly extruding and molding the present adhesive composition I or II, or by injecting the composition into a mold, without using adherends or mold release films as described above.

Furthermore, the present adhesive sheets I and II can also be formed by directly filling the present adhesive composition I or II between the adherends such as image display device constituting members.

<<Present Laminate Sheet>>

A laminate sheet (referred to as “present laminate sheet”) according to an example of the embodiment of the present invention includes a resin sheet or a thin film glass on at least one surface of the present adhesive sheet I or II (see FIG. 7).

Examples of the resin sheet include resin sheets containing, as a main component resin, one or more resins selected from the group consisting of cycloolefin resins, triacetyl cellulose resins, polymethyl methacrylate resins, epoxy resins, polyester resins, and polyimide resins.

The term “main component resin” means a resin having the highest mass ratio among the resins constituting the resin sheet, and the mass ratio is 50% by mass or more of the resins constituting the resin sheet, preferably 60% by mass or more, more preferably 70% by mass or more, even more preferably 80% by mass or more, still more preferably 90% by mass or more, and particularly preferably 95% by mass or more (including 100% by mass).

Examples of the thin film glass include glass having bending resistance such as ultra-thin glass (G-Leaf, manufactured by Nippon Electric Glass Co., Ltd.).

<<Present Coating-Type Polarization Element with Adhesive Layer>>

A coating-type polarization element with an adhesive layer (referred to as “present coating-type polarization element with an adhesive layer”) according to an example of the embodiment of the present invention is a coating-type polarization element with an adhesive layer including an adhesive layer I (referred to as “present adhesive layer I”) formed from the present adhesive composition I, or the present adhesive sheet I on at least one surface of a coating-type polarization element.

The present coating-type polarization element with an adhesive layer may be, for example, an adhesive sheet with a polarization element including a coating-type polarization element on at least one surface of the present adhesive sheet I.

The adhesive sheet with a polarization element can be produced, for example, by forming a polarization element on a substrate having releasability and then transferring the polarization element on the surface of the present adhesive sheet I, by directly molding the present adhesive sheet I on a coating-type polarization element, or by forming a coating-type polarization element on the present adhesive sheet I.

The present coating-type polarization element with an adhesive layer may also be a polarization element with an adhesive layer including a coating-type polarization element on at least one surface of the present adhesive layer I.

In this case, the present adhesive layer I may be directly formed on a coating-type polarization element, or an adhesive layer composed of the present adhesive composition I may be formed on another substrate and then transferred onto a coating-type polarization element.

Furthermore, the present coating-type polarization element with an adhesive layer may have a structure in which the coating-type polarization element and the present adhesive layer I or the present adhesive sheet I are directly laminated or other members are interposed therebetween. In either case, the effects of the present invention can be enjoyed.

Examples of the “other members” include a reflective sheet, a light guide plate and a light source, a diffusion film, a prism sheet, a liquid crystal panel, an organic EL panel, an anti-reflection film, a color filter, a polarization plate, a retardation plate, a glass substrate, a cover glass, and a cover plastic; or an integrally combined product composed of two or more of these members.

<Coating-Type Polarization Element>

The coating-type polarization element is, as described above, a laminate including a film formed by coating an optically anisotropic composition containing a liquid crystal compound. For example, an optically anisotropic composition containing a liquid crystal compound can be coated on an orientation film formed on a substrate to make the optically anisotropic composition oriented, and then cured in the oriented state to form an optically anisotropic layer. The optically anisotropic layer with the substrate or the optically anisotropic layer peeled off from the substrate can then be used to produce various optically anisotropic members. The optically anisotropic members may have an optically anisotropic layer made of an optically anisotropic composition and an orientation film. Alternatively, they may have only an optically anisotropic layer without an orientation film.

Examples of the liquid crystal compound include polymerizable liquid crystal compounds, polymer liquid crystal compounds, and lyotropic liquid crystal compounds.

Conventional polarization plates generally have a structure in which a polyvinyl alcohol (PVA) film is sandwiched between protective films such as triacetyl cellulose (TAC) films, and coated with an adhesive or laminated with an adhesive sheet.

However, polarization plates using an optically anisotropic layer composed of a coating-type polarization element can be thinner than conventional polarization elements because the film can be formed by coating.

Conventional retardation plates are generally obtained by stretching polycarbonate or other resin sheets, and have limitations in thinning because the sheets tend to break if made too thin.

However, retardation plates using an optically anisotropic layer composed of a coating-type polarization element can be made thinner than conventional stretched sheets because they can be easily made into thin films.

The use of circular polarization plates using such polarization plates and/or retardation plates composed of the coating-type polarization element in image display devices enables to contribute to the thinning of image display devices.

Examples of the “substrate” for forming the coating-type polarization element include a resin sheet or glass mainly composed of one or more resins selected from the group consisting of polyolefin resins, cyclic polyolefin resins, polyester resins, poly(meth)acrylic ester resins, cellulose ester resins, polycarbonate resins, and polyimide resins. Other layers such as an antistatic layer, a hard coat layer, an anchor layer, a mold release layer, an easy-adhesion layer, a protective layer, an anti-bleeding layer, and a flattening layer may be formed on the substrate as necessary.

The liquid crystal compound can be oriented by a method using an orientation control force by an orientation film provided on the substrate, an orientation control force by an external field such as an electric field or a magnetic field, and/or a shear force during coating. In particular, a method using an orientation film is preferred from the viewpoint of obtaining a polymerizable liquid crystal compound in a highly ordered orientation state to have a coating-type polarization element exhibiting good optical performance.

The orientation film provided on the substrate is a layer having an orientation control force for orienting a polymerizable liquid crystal compound described below in a desired direction. The orientation film preferably has solvent resistance that does not dissolve when coated with an optically anisotropic composition solution, moderate solution affinity that does not repel an optically anisotropic composition solution, and heat resistance in heat treatment during solvent drying and liquid crystal orientation.

The orientation film may be subjected to an orientation treatment to control the orientation direction. Examples of the orientation treatment method include known methods described in “Liquid Crystal Handbook” (published by Maruzen Co., Ltd., Oct. 30, 2000), pp. 226-239, (such as a rubbing method, a method of forming grooves (fine groove structure) on the orientation film surface, a method using polarized ultraviolet light or polarized laser (photo-orientation method), an orientation method by LB film formation, and an orientation method by oblique vapor deposition of inorganic substances). In particular, a rubbing method and a photo-orientation method are preferred from the viewpoint of easily obtaining a high degree of orientation.

The thickness of the orientation film is usually 10 nm to 1,000 nm, preferably 50 nm to 800 nm. The above range allows both sufficient orientation control force to orient a polymerizable liquid crystal compound, and thin films.

The optically anisotropic composition may be a composition containing, in addition to the liquid crystal compound, various additives and solvents, such as a polymerization initiator, optionally a polymerization inhibitor, a polymerization aid, a polymerizable non-liquid crystal compound, a surfactant, a leveling agent, a coupling agent, a pH adjusting agent, a dispersant, an antioxidant, organic and inorganic fillers, and a metal oxide. A cured product layer of the present composition exhibits optical functions as a polarization element.

When the polarization element is a polarization film, the optically anisotropic composition preferably contains a dichroic dye. Examples of the dichroic dye include iodine and dichroic organic dyes. The dichroic dye used may be one type or a combination of several different dyes.

Examples of the dichroic organic dyes include, but are not limited to, azo-based dyes, quinone-based dyes (including naphthoquinone-based dyes, anthraquinone-based dyes, and the like), stilbene-based dyes, cyanine-based dyes, phthalocyanine-based dyes, indigo-based dyes, and condensed polycyclic dyes (including perylene-based dyes, oxazine-based dyes, acridine-based dyes, and the like). Among these dyes, azo-based dyes are preferred because of their large molecular length-to-short axis ratio and good dichroism.

(Polymerizable Liquid Crystal Compound)

The polymerizable liquid crystal compound is a liquid crystal compound having a polymerizable functional group, and has both properties of a polymerizable monomer and a liquid crystal, so that the orientation can be fixed by crosslinking the polymerizable functional group while the liquid crystal is oriented and optical anisotropy can be exhibited. The polymerizable liquid crystal compound to be used may be one type or a combination of several compounds having different structures.

The polymerizable liquid crystal compound to be used may be either a low molecular liquid crystal compound having a polymerizable functional group or a high molecular liquid crystal compound having a polymerizable functional group. Among them, the polymerizable liquid crystal compound is preferably a low molecular liquid crystal compound because it tends to provide a cured product exhibiting a high degree of orientation.

The liquid crystal phase exhibited by the polymerizable liquid crystal compound can be appropriately selected from a nematic liquid crystal, a smectic liquid crystal, a cholesteric liquid crystal, and a discotic liquid crystal, and from the viewpoint of ease of production and obtaining a highly ordered orientation state, a nematic liquid crystal and a smectic liquid crystal are preferred.

The polymerizable functional group is preferably a photopolymerizable group in terms of ease of fixing the oriented structure. Specific examples thereof include an acryloyl group, a methacryloyl group, an acryloyloxy group, a methacryloyloxy group, an acryloylamino group, a methacryloylamino group, a vinyl group, a vinyloxy group, an ethynyl group, an ethynyloxy group, a 1,3-butadienyl group, a 1,3-butadienyloxy group, an oxiranyl group, an oxetanyl group, a glycidyl group, a glycidyloxy group, a styryl group, and a styryloxy group. Among them, a (meth)acryloyl group is preferred.

The polymerizable liquid crystal compound may use a liquid crystal compound having a polymerizable group without any particular limitation in molecular structure. Examples of the polymerizable liquid crystal compound contained in the optically anisotropic composition include a compound represented by the following formula (1) (hereinafter may be referred to as “polymerizable liquid crystal compound (1)”).

Q¹-R¹-A¹¹-Y¹-A²-(Y²-A¹³)ₖ—R²-Q² (1)

In the formula (1),
-Q¹ represents a hydrogen atom or a polymerizable group;
-Q² represents a polymerizable group;
—R¹- and R²— each independently represent a chain organic group;
-A¹¹- and A¹³- each independently represent a substructure represented by the following formula (2), a divalent organic group, or a single bond;
-A¹²- represents a substructure represented by the following formula (2) or a divalent organic group;
—Y¹— and Y²— each independently represent a single bond, —C(═O)O—, —OC(═O)—, —C(═S)O—, —OC(═S)—, —C(═O)S—, —SC(═O)—, —CH₂CH₂—, —CH═CH—, —C≡C—, —C(═O)NH—, —NHC(═O)—, —CH₂O—, —OCH₂—, —CH₂S—, or SCH₂—;
one of -A¹¹- and A¹³- is a substructure represented by the following formula (2) or a divalent organic group; and
k is 1 or 2.

When k is 2, the two —Y²-A¹³- may be identical or different from each other.

Cy-X²—C≡C—X¹— (2)

In the formula (2),
-Cy- represents a hydrocarbon cyclic group or a heterocyclic group;
—X¹— represents —C(═O)O—, —OC(═O)—, —C(═S)O—, —OC(═S)—, —C(═O)S—, —SC(═O)—, —CH₂CH₂—, —CH═CH—, —C(═O)NH—, —NHC(═O)—, —CH₂O—, —OCH₂—, —CH₂S—, or —SCH₂—; and
—X²— represents a single bond, —C(═O)O—, —OC(═O)—, —C(═S)O—, —OC(═S)—, —C(═O)S—, —SC(═O)—, —CH₂CH₂—, —CH═CH—, —C(═O)NH—, —NHC(═O)—, —CH₂O—, —OCH₂—, —CH₂S—, or —SCH₂—.

When -A¹¹- is a substructure represented by the formula (2), the formula (1) may be the following formula (1A) or the following formula (1B).

Q¹-R¹-Cy-X²—C≡C—X¹—Y¹-A¹²-(Y²-A¹³)ₖ-R²-Q² (1A)

Q¹-R¹—X¹—C≡C—X²-Cy-Y¹-A¹²-(Y²-A¹³)ₖ—R²-Q² (1B)

When -A¹²- is a substructure represented by the formula (2), the formula (1) may be the following formula (1C) or the following formula (1D).

Q¹-R¹-A¹¹-Y¹-Cy-X²—C≡C—X¹—(Y²-A¹³)ₖ—R²-Q² (1C)

Q¹-R¹-A¹¹-Y¹—X¹—C≡C—X²-Cy-(Y²-A¹³)ₖ-R²-Q² (1D)

When -A¹³- is a substructure represented by the formula (2), the formula (1) may be the following formula (1E) or the following formula (1F).

Q¹-R¹-A¹¹-Y¹-A¹²-(Y²-Cy-X²—C≡C—X¹)ₖ—R²-Q² (1E)

Q¹-R¹-A¹¹-Y¹-A¹²-(Y²—X¹—C≡C—X²-Cy)ₖ-R²-Q² (1F)

Similarly, when two or more of -A¹¹-, -A¹²-, and -A¹³- each are a substructure represented by the formula (2), the orientation of the substructure represented by the formula (2) may be independently reversed.

Although, as described above, -A¹¹-, -A¹²-, and -A¹³- are each independently a substructure represented by formula (2) or a divalent organic group, and -A¹¹- and A¹³- may be each independently a single bond, both -A¹¹- and A¹³- may not be single bonds.

The polymerizable liquid crystal compound (1) is preferably a compound represented by the formula (1A), (1B), (1E), or (1F) because it tends to provide a high degree of orientation.

When the polymerizable liquid crystal compound is photopolymerized, the optically anisotropic composition preferably contains a photopolymerization initiator. A known photopolymerization initiator may be used accordingly.

The thickness of the cured film of the optically anisotropic composition is preferably 100 nm or more, more preferably 300 nm or more, and even more preferably 1 μm or more, from the viewpoint of securing the optical functions.

In addition, the upper limit of the thickness is preferably 50 μm or less, more preferably 10 μm or less, and even more preferably 5 μm or less, from the viewpoint of contributing to thinning of image display devices.

Other layers such as an overcoat layer, an antistatic layer, a hard coat layer, an anchor layer, a mold release layer, an easy-adhesion layer, a protective layer, an anti-bleeding layer, and a flattening layer may be formed on the cured film of the optically anisotropic composition as necessary.

<<Present Adhesive Sheet with Polarization Element>>

An adhesive sheet with a polarization element (referred to as “present adhesive sheet with a polarization element”) according to an example of the embodiment of the present invention has a configuration with the present adhesive sheet I on at least one surface of a coating-type polarization element, in other words, with a coating-type polarization element on at least one surface of the present adhesive sheet I.

The present adhesive sheet with a polarization element can be obtained, for example, by forming a polarization element on a substrate having releasability and then transferring the polarization element on the surface of the present adhesive sheet I, by directly molding the present adhesive sheet I on a coating-type polarization element, or by molding the present adhesive sheet I and then forming a coating-type polarization element.

Furthermore, the present adhesive sheet with a polarization element may have a structure in which the coating-type polarization element and the present adhesive sheet I are directly laminated or other members are interposed therebetween. In either case, the effects of the present invention can be enjoyed.

Examples of the “other members” include the “other image display device constituting members”, such as a reflective sheet, a light guide plate and a light source, a diffusion film, a prism sheet, a liquid crystal panel, an organic EL panel, an anti-reflection film, a color filter, a polarization plate, a retardation plate, a glass substrate, a cover glass, and a cover plastic; or an integrally combined product composed of two or more of these members.

The coating-type polarization element of the present adhesive sheet with a polarization element is the same as the coating-type polarization element of the present coating-type polarization element with an adhesive layer.

<<Present Image Display Device Constituting Member with Adhesive Layer>>

An image display device constituting member with an adhesive layer (referred to as “present image display device constituting member with an adhesive layer”) according to an example of the embodiment of the present invention is an image display device constituting member with an adhesive layer including an adhesive layer II (referred to as “present adhesive layer II”) formed from the present adhesive composition II, or the present adhesive sheet II on at least one surface of an image display device constituting member.

The present image display device constituting member with an adhesive layer may be, for example, an adhesive sheet with an image display device constituting member including an image display device constituting member on at least one surface of the present adhesive sheet II.

The present image display device constituting member with an adhesive layer may also be an image display device constituting member with an adhesive layer including an image display device constituting member on at least one surface of the present adhesive layer II.

In this case, the present adhesive layer II may be directly formed on an image display device constituting member, or an adhesive layer composed of the present adhesive composition II may be formed on another substrate and then transferred onto an image display device constituting member.

Furthermore, the present image display device constituting member with an adhesive layer may have a structure in which the image display device constituting member and the present adhesive layer II or the present adhesive sheet II are directly laminated or other members are interposed therebetween. In either case, the effects of the present invention can be enjoyed.

Examples of the “other members” include a reflective sheet, a light guide plate and a light source, a diffusion film, a prism sheet, a liquid crystal panel, a retardation plate, a glass substrate, a polarization plate, an organic EL panel, an electrode, an anti-reflection film, a color filter, a touch sensor, a cover glass, and a cover plastic; or an integrally combined product composed of two or more of these members.

In addition to the above members, other layers such as an antistatic layer, a hard coat layer, an anchor layer, a mold release layer, an easy-adhesion layer, a protective layer, an anti-bleeding layer, and a flattening layer may be interposed as necessary.

<Image Display Device Constituting Member Using Coating-Type Polarization Element>

Examples of the image display device constituting member include optical members using a coating-type polarization element.

For the coating-type polarization element, the above description of the coating-type polarization element in the present coating-type polarization element with an adhesive layer applies. In addition, the above description of the polymerizable liquid crystal compound also applies.

<<Present Adhesive Sheet with Image Display Device Constituting Member>>

An adhesive sheet with an image display device constituting member (referred to as “present adhesive sheet with an image display device constituting member”) according to an example of the embodiment of the present invention has a configuration with the present adhesive sheet II on at least one surface of an image display device constituting member.

The present adhesive sheet with an image display device constituting member can be obtained, for example, by forming an image display device constituting member on a substrate having releasability and then transferring the image display device constituting member on the surface of the present adhesive sheet II, by directly molding the present adhesive sheet on an image display device constituting member, or by forming the image display device constituting member on the present adhesive sheet II.

Furthermore, the present adhesive sheet with an image display device constituting member may have a structure in which the image display device constituting member and the present adhesive sheet are directly laminated or other members are interposed therebetween. In either case, the effects of the present invention can be enjoyed.

Examples of the “other members” include a reflective sheet, a light guide plate and a light source, a diffusion film, a prism sheet, a liquid crystal panel, a retardation plate, a glass substrate, a polarization plate, an organic EL panel, an electrode, an anti-reflection film, a color filter, a touch sensor, a cover glass, and a cover plastic; or an integrally combined product composed of two or more of these members.

The image display device constituting member of the present adhesive sheet with an image display device constituting member is the same as the image display device constituting member of the present image display device constituting member with an adhesive layer.

<<Present Image Display Device>>

An image display device (referred to as “present image display device”) according to an example of the embodiment of the present invention is an image display device including the present adhesive layer I or II.

The present adhesive layer I or II is not limited in its form, and may be a sheet-shaped adhesive product previously formed into a sheet, that is, the present adhesive sheet I or II.

Examples of the present image display device include image display devices having a structure in which the present adhesive layer I or II composed of the present adhesive composition I or II, the coating-type polarization element or the image display device constituting member, and optionally other members such as other image display device constituting members are combined and laminated.

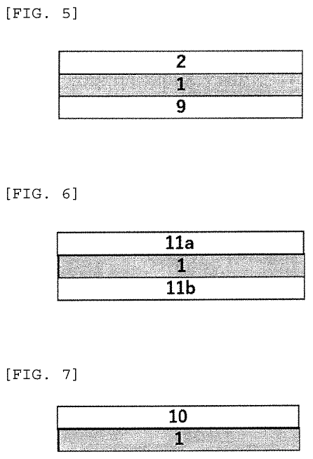

The present image display device may have a structure in which the coating-type polarization element or the image display device constituting member and the present adhesive layer I or II are directly laminated as shown in FIG. 2 or 4, or other members such as other image display device constituting members are interposed therebetween as shown in FIG. 3. In either case, the effects of the present invention can be enjoyed.

Examples of the “other image display device constituting members” include a reflective sheet, a light guide plate and a light source, a diffusion film, a prism sheet, the present laminate, a liquid crystal panel, a retardation plate, a glass substrate, a polarization plate, an organic EL panel, an electrode, an anti-reflection film, a color filter, a touch sensor, a cover glass, and a cover plastic; or an integrally combined product composed of two or more of these members.

In addition to the above members, other layers such as an antistatic layer, a hard coat layer, an anchor layer, a mold release layer, an easy-adhesion layer, a protective layer, an anti-bleeding layer, and a flattening layer may be interposed as necessary.

The present adhesive layers I and II in the present image display device are preferably arranged on the viewing side of the adherend such as the coating-type polarization element or the image display device constituting member. Specifically, the present adhesive layer I or II is preferably used for laminating a cover glass or a cover plastic. With this configuration, the deterioration of the polarization element or the image display device constituting member due to external incident light can be suppressed.

In an organic EL display device including the present adhesive layer II (see FIG. 5), when the organic EL display device has a configuration in which a color filter, a black matrix, and optionally an anti-reflection layer are built-in and integrated (color filter built-in organic EL panel), the present adhesive layer II or the present adhesive sheet II is preferably arranged on the viewing side of the organic EL panel.

The color filter built-in organic EL panel is capable of reducing external light reflection by the color filter, black matrix, and anti-reflection layer built into the panel, which eliminates a polarization plate and retardation plate (circular polarization plate) used in conventional organic EL panels and contributes to further thinning and weight reduction of the image display device.

In addition, the color filter built-in organic EL panel eliminates the loss of light emission caused by the circular polarization plate absorbing light emitted from the organic EL element, which dramatically improves the luminous efficiency of the organic EL element and the luminous lifetime of the organic EL element, and contributes to further improving the performance of the image display device.

By arranging the present adhesive layer II or the present adhesive sheet II on the viewing side of the organic EL panel, the deterioration of the organic EL panel due to external incident light can be suppressed.

Specific examples of the present image display device include liquid crystal displays, organic EL displays, inorganic EL displays, electronic paper, plasma displays, and micro electro-mechanical system (MEMS) displays.

The present laminate sheet described above can also be used on the surface of the cover glass or cover plastic of the present image display device.

The present adhesive layer I or II has the light transmittance, b* value, gel fraction, and thickness characteristics as in the present adhesive sheet I or II, and the preferred range of each characteristic indicated in the present adhesive sheet I or II can be enjoyed.

<Explanation of Terms and Phrases>

In the case of being expressed as the term “X to Y” (X and Y are arbitrary numbers) in the present invention, unless otherwise stated, the term includes the meaning of “preferably more than X” or “preferably less than Y” along with the meaning “X or more and Y or less”.

Further, in the case of being expressed as the term “X or more” (X is an arbitrary number) or the term “Y or less” (Y is an arbitrary number), the term also includes the intention of being “preferably more than X” or “preferably less than Y”.

In the present invention, the term “sheet” conceptually includes a sheet, a film, and a tape.

### EXAMPLES

Hereinafter, the present invention will be described in more details with reference to the following Examples and Comparative Examples. However, the present invention is not limited to the following Examples.

<<Description of Raw Materials>>

In the following Examples and Comparative Examples, raw materials used for preparing adhesive compositions will be described.

[(Meta)Acrylic Polymer (A)]
(Meta)acrylic polymer (A-1): Acrylic acid ester copolymer polymer composed of 67% by mass of 2-ethylhexyl acrylate, 5% by mass of methyl acrylate, 10% by mass of ethyl acrylate, 14% by mass of 2-hydroxyethyl acrylate, and 4% by mass of 4-hydroxybutyl acrylate; the mass average molecular weight (Mw) of the acrylic acid ester copolymer polymer measured by GPC was 700,000.
(Meta)acrylic polymer (A-2): Acrylic acid ester copolymer polymer in which a polymerizable carbon double bond group was introduced into the side chain by reacting 0.06 part by mass of 2-methacryloyloxyethyl isocyanate with 100 parts by mass of a copolymer obtained by copolymerizing 85% by mass of butyl acrylate and 15% by mass of 2-hydroxyethyl acrylate in an ethyl acetate solution; the mass average molecular weight (Mw) of the acrylic acid ester copolymer polymer measured by GPC was 900,000.

[Ultraviolet Absorber (B)]
Ultraviolet absorber (B-1): 2,2′-Dihydroxy-4-methoxybenzophenone (KEMISORB 111, manufactured by Chemipro Kasei Kaisha, Ltd.)
Ultraviolet absorber (B-2): 2,2′,4,4′-Tetrahydroxybenzophenone (SEESORB 106, manufactured by Shipro Kasei Kaisha, Ltd.)
Ultraviolet absorber (B-3): 2-(5-Chloro-2H-benzotriazol-2-yl)-4-methyl-6-tert-butylphenol (Tinuvin 326, manufactured by BASF)
Hydroxy group-containing benzophenone compound (B1-1): 2,2′-Dihydroxy-4-methoxybenzophenone (KEMISORB 111, manufactured by Chemipro Kasei Kaisha, Ltd.)
Hydroxy group-containing benzophenone compound (B1-2): 2,2′,4,4′-Tetrahydroxybenzophenone (SEESORB 106, manufactured by Shipro Kasei Kaisha, Ltd.)

[Radical Polymerization Initiator (C)]
Photocleavage-type radical polymerization initiator (C-1): 2,4,6-Trimethylbenzoyl-diphenyl phosphine oxide (Omnirad TPO H, manufactured by IGM Resins B.V.)

[Polyfunctional (Meth)Acrylate (D)]
Polyfunctional (meth)acrylate (D-1): Polypropylene glycol #700 diacrylate (APG-700, manufactured by Shin-Nakamura Chemical Co., Ltd., molecular weight of 823)
Polyfunctional (meth)acrylate (D-2): Bifunctional urethane acrylate (SHIKOH UV-3700B, manufactured by Mitsubishi Chemical Corp., molecular weight of 38,000)

[Others]
Solvent: Ethyl acetate
Silane coupling agent: 3-Glycidoxypropyl methyl diethoxysilane (KBM-403, manufactured by Shin-Etsu Silicone)
Rust inhibitor: 1,2,3-Triazole

<Preparation of Coating-Type Polarization Elements (Image Display Device Constituting Members)>

Coating-type polarization elements as image display device constituting members used for evaluation, as well as polymerizable liquid crystal compounds and dyes contained in the coating-type polarization elements will be described.

(Synthesis of Polymerizable Liquid Crystal Compounds)

[Liquid Crystal Compound (I-1)]

A liquid crystal compound (I-1) represented by the following formula (I-1) was synthesized according to the description in Japanese Patent Laid-Open No. 2020-042305.

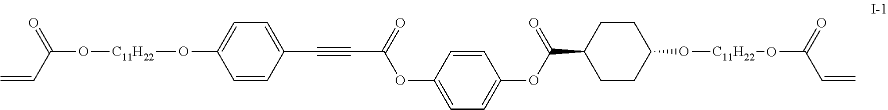

(Synthesis of Dyes)

[Dye (II-1)]

A dye (II-1) represented by the following formula (II-1) was synthesized according to the synthesis method described below.

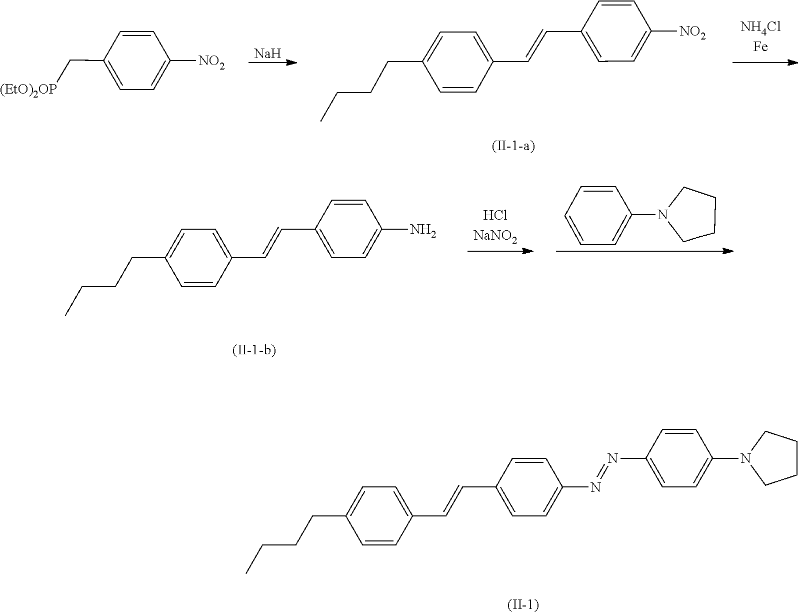

Synthesis of (II-1-a):

Tetrahydrofuran (100 mL), sodium hydride (60% purity, 6.7 g, 168.0 mmol) were added to an ice-cooled reactor; and a mixture of diethyl (4-nitrobenzyl)phosphonate (18.0 g, 65.9 mmol), 4-butylbenzaldehyde (9.1 g, 56.1 mmol), and tetrahydrofuran (50 mL) was added dropwise over 10 minutes, followed by washing with tetrahydrofuran (30 mL) and stirring at 50° C. for 0.5 hour. The reaction solution was poured into water, extracted with ethyl acetate, and washed with water and saturated salt water, and the solvent was distilled off. The resulting crude material was heated and dissolved in ethyl acetate (20 mL), hexane (50 mL) was added for cooling, and the deposited precipitate was separated by filtration, washed with hexane, and then dried under reduced pressure to obtain 15.0 g of (II-1-a).

Synthesis of (II-1-b):

The (II-1-a) (15.0 g, 53.3 mmol), tetrahydrofuran (150 mL), and iron powder (13.9 g, 248.9 mmol) were mixed, and ammonium chloride (13.3 g, 248.6 mmol) that was dissolved in water (30 mL) was added dropwise, followed by stirring at 50° C. for 3 hours. The reaction solution was filtered using celite, extracted with ethyl acetate, and washed with water and saturated salt water, and the solvent was distilled off. The resulting crude material was suspended in hexane, and the precipitate was separated by filtration, washed with hexane, and then dried to obtain 10.9 g of (II-1-b).

Synthesis of (II-1):

The (II-1-b) (2.51 g, 10.0 mmol), N-methylpyrrolidone (40 mL), concentrated hydrochloric acid (2.2 mL), and water (20 mL) were mixed, cooled to 3° C., and added with sodium nitrite (789 mg, 11.4 mmol), followed by stirring at 15° C. for 3.5 hours.

One(1)-Phenylpyrrolidine (1.47 g, 10.0 mmol), methanol (60 mL), and water (30 mL) were mixed and adjusted to pH 3.5 with concentrated hydrochloric acid. A sodium hydroxide aqueous solution was added thereto to maintain the pH at 3 to 5, and the above-mentioned solution containing the diazonium salt was added dropwise, followed by stirring at 15° C. for 3 hours.

The resulting precipitate was filtered, washed with water, and dried under reduced pressure. The resulting crude material was purified by silica gel column chromatography (hexane/methylene chloride) to obtain 3.06 g of dye (II-1) as a red solid.

[Dye (II-2)]

A dye (II-2) represented by the following formula (II-2) was synthesized according to the synthesis method described below.

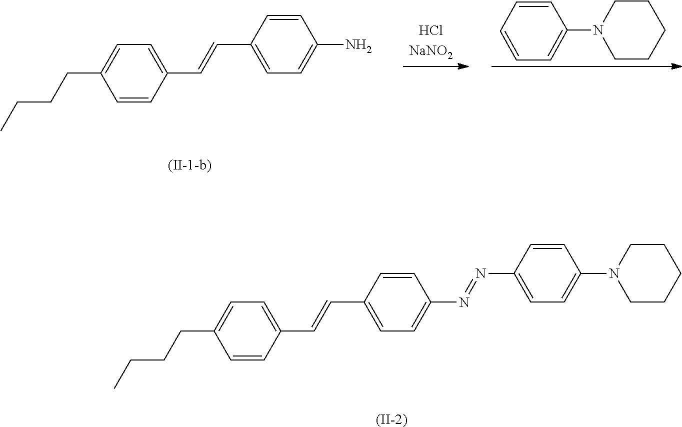 [SMILES: CCCCc1ccc(/C=C/c2ccc(N)cc2)cc1 ; c1ccc(N2CCCCC2)cc1 ; CCCCc1ccc(/C=C/c2ccc(/N=N/c3ccc(N4CCCCC4)cc3)cc2)cc1 ; "(II-2)"]

Synthesis of (II-2):

The (II-1-b) (1.0 g, 4.0 mmol) and N-methylpyrrolidone (13 mL) were mixed, added with concentrated hydrochloric acid (1.0 g, 10.0 mmol), cooled in an ice bath, and added with sodium nitrite (0.3 g, 4.4 mmol) that was dissolved in water (1.3 mL), followed by stirring for 1 hour. The reaction solution was coupled at pH 7 with methanol (25 mL) and 1-phenylpiperidine (0.6 g, 4.0 mmol) that was dissolved in water (6.5 mL), and the precipitate was then separated by filtration, washed with water, and dried under reduced pressure. The resulting crude material was purified by silica gel column chromatography (hexane/methylene chloride) to obtain 760 mg of dye (II-2) as an orange solid.

The chemical structures of the liquid crystal compounds and dyes synthesized above are shown below. In the formula, C₁₁H₂₂ means that 11 methylene chains were linearly bonded.

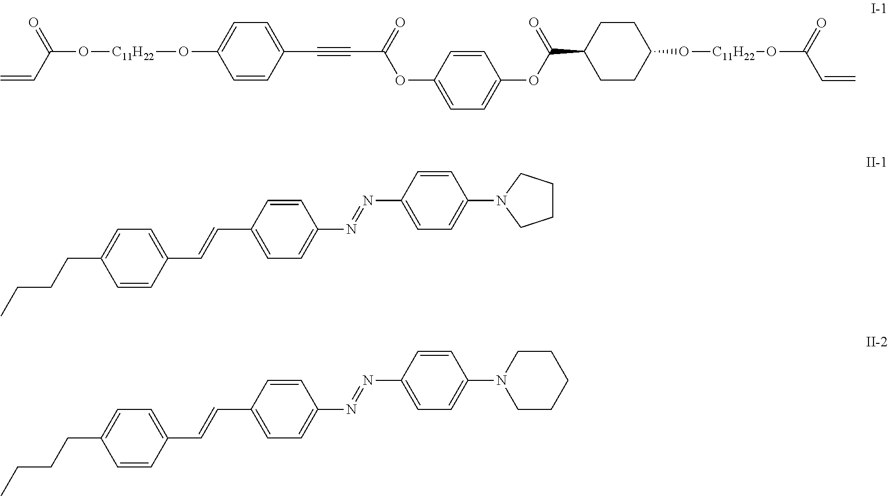

The chemical structures of dyes (II-3) and (II-4) used in Examples and Comparative Examples are shown below.

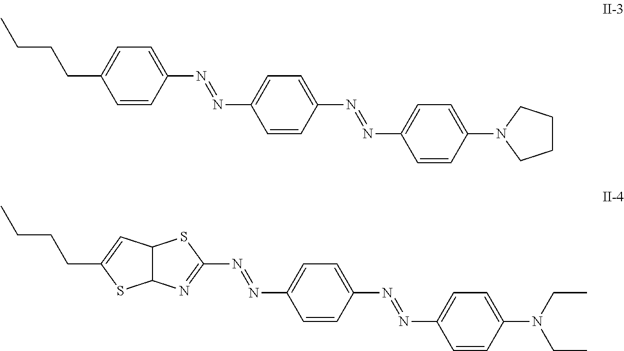 [SMILES: CCCCc1ccc(/N=N/c2ccc(/N=N/c3ccc(N4CCCC4)cc3)cc2)cc1 ; CCCCC1=CC2SC(/N=N/c3ccc(/N=N/c4ccc(N(CC)CC)cc4)cc3)=NC2S1]

(Preparation of Optically Anisotropic Composition)

An optically anisotropic composition was obtained as follows: 69.31 parts of cyclopentanone was added with 28.57 parts of the liquid crystal compound (I-1), 0.10 part of the dye (II-1), 0.43 part of the dye (II-2), 0.39 part of the dye (II-3) (manufactured by Hayashibara Co., Ltd.), 0.90 part of the dye (II-4) (manufactured by Showa Kako Corp.), 0.23 part of the following initiator (PI-1), and 0.34 part of BYK-361N (manufactured by BYK-Chemie); and the mixture was heated and stirred at 80° C., and filtered using a syringe equipped with a syringe filter (PTFE13045, manufactured by Membrane Solutions Ltd., diameter of 0.45 μm).

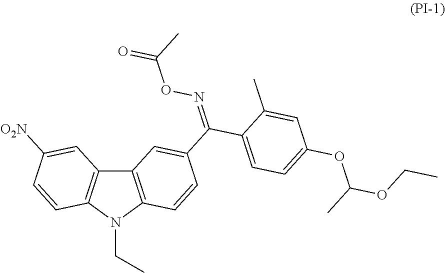 [SMILES: CCOC(C)Oc1ccc(/C(=N/OC(C)=O)c2ccc3c(c2)c2cc([N+](=O)[O-])ccc2n3CC)c(C)c1]

(Production of Coating-Type Polarization Element)

The optically anisotropic composition prepared above was film-formed by spin coating on a substrate having a polyimide orientation film (LX1400, manufactured by Hitachi Chemical DuPont Microsystems Ltd., orientation film formed by rubbing) formed on a glass, heated and dried at 120° C. for 2 minutes, cooled to a liquid crystal phase, and polymerized at an exposure amount of 500 mj/cm² (at 365 nm) to obtain a coating-type polarization element having a thickness of approximately 3 μm.

In addition, an overcoat layer was further provided on top of the coating-type polarization element using an overcoat composition by the method described below.

A curable (meth)acryloyl copolymer (R-1) contained in the overcoat composition was synthesized by the following method.

Propylene glycol monomethyl ether (157 parts by mass), glycidyl methacrylate (98 parts by mass), methyl methacrylate (1.0 part by mass), ethyl acrylate (1.0 part by mass), 2,2′-azobis(2,4-dimethylvaleronitrile) (1.0 part by mass), and γ-trimethoxysilylpropanethiol (KBM-803, manufactured by Shin-Etsu Chemical Co., Ltd.) (1.9 parts by mass) were added into a flask equipped with a thermometer, a stirrer, and a reflux cooling tube, and allowed to react at 65° C. for 3 hours.

Subsequently, 2,2′-azobis(2,4-dimethylvaleronitrile) (0.5 part by mass) was further added and allowed to react for 3 hours, and then propylene glycol monomethyl ether (138 parts by mass) and p-methoxyphenol (0.45 part by mass) were added and heated to 100° C.

Then, acrylic acid (51 parts by mass) and triphenylphosphine (3.1 parts by mass) were added and allowed to react at 110° C. for 6 hours to obtain a (meth)acryloyl copolymer (R-1) having a carbon-carbon double bond amount (acryloyl equivalent (amount of acryloyl group introduced)) of 4.6 mmol/g. The mass average molecular weight (Mw) was 17,700.

Next, 23.08 parts of the curable (meth)acryloyl copolymer (R-1), which was 65% propylene glycol monomethyl ether solution, 0.13 part of the following photopolymerization initiator (PI-2), 0.40 part of BYK-3550 (manufactured by BYK-Chemie), and 76.39 parts of ethanol were added and stirred to obtain an overcoat composition.

The overcoat composition was film-formed on top of the coating-type polarization element by spin coating, heated and dried at 50° C. for 2 minutes, polymerized at an exposure amount of 500 mj/cm² (at 365 nm), and then heated at 80° C. for 5 minutes to laminate an overcoat layer having a thickness of approximately 5 μm, thereby obtaining a coating-type polarization element with an overcoat layer.

When the obtained coating-type polarization element with an overcoat layer was rotated while being held over a commercially available polarization plate, it was confirmed to be bright and dark, indicating good performance for use as a polarization film.

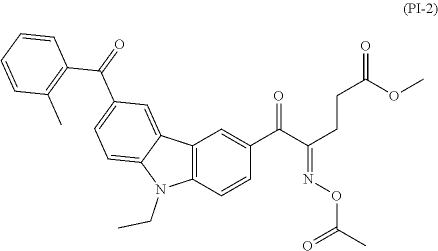 [SMILES: CCn1c2ccc(C(=O)/C(CCC(=O)OC)=N/OC(C)=O)cc2c2cc(C(=O)c3ccccc3C)ccc21]

### Example I-1

An adhesive composition I-1 was prepared by uniformly mixing 200 parts by mass of the (meth)acrylic polymer (A-1) solution (dilution solvent: ethyl acetate, solid content concentration of 50% by mass), 6 parts by mass of the ultraviolet absorber (B-1), 3 parts by mass of the photocleavage-type radical polymerization initiator (C-1), 25 parts by mass of the polyfunctional (meth)acrylate (D-1) 0.3 part by mass of 3-glycidoxypropyl methyl diethoxysilane (KBM-403, manufactured by Shin-Etsu Silicone) as a silane coupling agent, 0.3 part by mass of 1,2,3-triazole as a rust inhibitor, and 101 parts by mass of ethyl acetate.

The adhesive composition I-1 after solvent drying was formed into a sheet shape on a silicone release-treated mold release film (Diafoil MRV, manufactured by Mitsubishi Chemical Corp.) having a thickness of 100 μm, so as to have a thickness of 50 μm.

Next, the sheet-shaped adhesive composition I-1 together with the mold release film was placed in a drying apparatus heated to 95° C. and held for 10 minutes to volatilize the solvent contained in the adhesive composition I-1.

Then, a silicone release-treated mold release film (Diafoil MRQ, manufactured by Mitsubishi Chemical Corp.) having a thickness of 75 μm was laminated on the sheet-shaped adhesive composition I-1 after drying the solvent to form a laminate, and the adhesive composition I-1 was irradiated with light through the mold release film using a high-pressure mercury lamp, such that the accumulative irradiation amount at a wavelength of 365 nm was 1,000 mJ/cm² and the accumulative irradiation amount at a wavelength of 405 nm was 1,400 mJ/cm², thereby obtaining an adhesive sheet I-1 with mold release films (adhesive sheet thickness of 50 μm) having mold release films laminated on both front and back sides.

### Examples I-2 to I-4 and Comparative Examples I-1 to I-2

Adhesive compositions I-2 to I-6 and adhesive sheets I-2 to I-6 with mold release films were prepared in the same manner as in Example I-1, except that the types and amounts of the (meth)acrylic polymer (A), the ultraviolet absorber (B), the radical polymerization initiator (C), the polyfunctional (meth)acrylate (D), and other additives used were those shown in Table 1.

<Evaluation>

The adhesive compositions I-1 to I-6 and the adhesive sheets I-1 to I-6 obtained in Examples and Comparative Examples were measured and evaluated as follows.

[Light Transmittance]

The mold release films on both sides of the adhesive sheet with mold release films prepared in each of Examples and Comparative Examples were sequentially peeled off; and the adhesive sheet (thickness of 50 μm) was adhered so as to be sandwiched between two sheets of soda lime glass (thickness of 0.5 mm) and subjected to an autoclave treatment (60° C., gauge pressure of 0.2 MPa, and 20 minutes) for finishing adhesion, thereby preparing a sample for optical property evaluation.

The light transmittance in the wavelength range of 360 nm to 430 nm of the prepared sample for optical property evaluation was measured using a spectrophotometer (apparatus name “UV2450”, manufactured by Shimadzu Corp.).

[b* Value]

The b* value of the prepared sample for optical property evaluation was measured using a spectrocolorimeter (apparatus name “SC-P”, manufactured by Suga Test Instruments Co., Ltd.) in accordance with JIS Z 8781-4.

[Gel Fraction]

The gel fraction of the adhesive composition obtained as intermediate substance in preparing each of Examples and Comparative Examples was measured by the following procedure:
1) the adhesive composition was weighed (W1), and wrapped in a pre-weighed SUS mesh (W0);
2) the SUS mesh was immersed in 100 mL of ethyl acetate for 24 hours;
3) the SUS mesh was taken out and dried at 75° C. for 4.5 hours; and
4) the mass after drying (W2) was measured, and the gel fraction of the adhesive composition was determined by the following formula.

Gel fraction (%)=100×(W2−W0)/W1

[Adhesive Force]

For the adhesive sheet with mold release films prepared in each of Examples and Comparative Examples, one of the mold release films was peeled off, and a polyethylene terephthalate film (“Cosmoshine A4300” with a thickness of 100 μm, manufactured by TOYOBO Co., Ltd.) serving as a backing film was roll-pressed thereon using a hand roller. This was cut into a strip shape of 10 mm width×100 mm length, and the adhesive surface exposed by peeling off the remaining mold release film was roll-bonded on a sheet of soda lime glass using a hand roller. The laminate was subjected to an autoclave treatment (60° C., gauge pressure of 0.2 MPa, and 20 minutes) for finishing adhesion to prepare an adhesive force measurement sample.

Using a universal material testing system (apparatus name “5965”, manufactured by Instron), the adhesive sheet was peeled off from the glass while pulling the backing film at an angle of 180° and a peeling speed of 60 mm/min, and the tensile strength was measured using a load cell to determine the 180° peel strength (N/cm) of the adhesive sheet against the glass. The results are shown in Table 1 as “Adhesive force”.

[Protection Function for Coating-Type Polarization Element]

For the adhesive sheet with mold release films prepared in each of Examples and Comparative Examples, one of the mold release films was peeled off, the adhesive sheet was roll-pressed on the overcoat layer of the coating-type polarization element using a hand roller, and the adhesive surface exposed by peeling off the remaining mold release film was roll-bonded on a sheet of soda lime glass using a hand roller. The laminate was subjected to an autoclave treatment (60° C., gauge pressure of 0.2 MPa, and 20 minutes) for finishing adhesion to prepare a sample for measuring a protection function for the coating-type polarization element.

The sample was subjected to a light resistance test for 40 hours under ultraviolet irradiation conditions at an illuminance of 0.55 W/cm² (340 nm) using a xenon light resistance tester (apparatus name “Cab 4000”, manufactured by ATLAS).

The value of the change in the polarization degree at a wavelength of 595 nm before and after the light resistance test (the polarization degree before the test—the polarization degree after the test) is shown in Table 1 as a result of the light resistance test.

Linearly polarized measurement light was made incident on the anisotropic dye film to measure “transmittance to polarization in the direction of absorption axis of the anisotropic dye film” and “transmittance to polarization in the direction of polarization axis of the anisotropic dye film” using a spectrophotometer equipped with a Glan-Thompson polarizer (product name “RETS-100”, manufactured by Otsuka Electronics Co., Ltd.), and the polarization degree (Pe) was calculated according to the following formula.

Pe=(Ty−Tz)/(Ty+Tz)

wherein Tz represents the transmittance to polarization in the direction of absorption axis of the anisotropic dye film; and Ty represents the transmittance to polarization in the direction of polarization axis of the anisotropic dye film.

The samples were evaluated according to the following criteria.

◯ (good): Those having an amount of change in the polarization degree before and after the light resistance test of 0.25 or less.

X (poor): Those having an amount of change in the polarization degree before and after the light resistance test of more than 0.25.

The results obtained by the measurement and evaluation are shown in Table 1.

TABLE 1

| | | | | | | | | Comparative | Comparative |
|---|---|---|---|---|---|---|---|---|---|
| | | | | Example I-1 | Example I-2 | Example I-3 | Example I-4 | Example-1 | Example I-2 |
| | | | | Adhesive | Adhesive | Adhesive | Adhesive | Adhesive | Adhesive |
| | | | | sheet | sheet | sheet | sheet | sheet | sheet |
| | | | | I-1 | I-2 | I-3 | I-4 | I-5 | I-6 |
| Compo- | (Meth) [symbol] | A-1 | pa [symbol] s by mass | 100 | — | 100 | 100 | 100 | 100 |
| sition | polymer (A) | A-2 | pa [symbol] s by mass | — | 100 | — | — | — | — |
| | Ultroviolet | B-1 | pa [symbol] s by mass | 6 | 6 | — | — | 1 | — |
| | absorber (B) | B-2 | pa [symbol] s by mass | — | — | 6 | — | — | — |
| | | B-3 | pa [symbol] s by mass | — | — | — | 6 | — | — |
| | Radical | C-1 | pa [symbol] s by mass | 3 | 3 | 3 | 3 | 3 | 3 |
| | polymerization | | | | | | | | |
| | initiator (C) | | | | | | | | |
| | Polyfunctional | D-1 | pa [symbol] s by mass | 25 | — | 25 | 25 | 25 | 25 |
| | (meth)acryate | D-2 | pa [symbol] s by mass | — | 6 | — | — | — | — |
| | (D) | | | | | | | | |
| | Others | First inhibitor | pa [symbol] s by mass | 0.3 | 0.3 | 0.3 | 0.3 | 0.3 | 0.3 |
| | | Silane coupling | pa [symbol] s by mass | 0.3 | 0.3 | 0.3 | 0.3 | 0.3 | 0.3 |
| | | agent | | | | | | | |
| Evalu- | Light | 360 nm | % | 0 | 0 | 0 | 0 | 4 | 59 |
| ation | [symbol] ansmittance | 370 nm | % | 0 | 0 | 0 | 0 | 8 | 69 |
| | | 380 nm | % | 0 | 0 | 0 | 0 | 20 | 73 |
| | | 390 nm | % | 2 | 2 | 0 | 0 | 43 | 80 |
| | | 400 nm | % | 20 | 22 | 19 | 15 | 64 | 83 |
| | | 410 nm | % | 60 | 61 | 65 | 60 | 82 | 88 |
| | | 420 nm | % | 83 | 82 | 85 | [symbol] 2 | 89 | 90 |
| | | 430 nm | % | 88 | 88 | 9 [symbol] | 88 | 90 | 90 |
| | Adhesive force | | N/cm | 6.1 | 6.1 | 10.6 | 6.8 | 6.8 | 6.0 |
| | Gel fraction | | % | 51 | 71 | 49 | 46 | 57 | 56 |
| | b′ | | — | 1.8 | 2.2 | 1.7 | 2.4 | 0.7 | 0.4 |
| | T(360) × b′ | | — | 0.1 | 0.2 | 0. [symbol] | 0.1 | 14.5 | 31.2 |
| | T(430) × b′ | | — | 157 [symbol] 4 | 196 [symbol] 8 | 153 [symbol] 6 | 211 [symbol] 8 | 6 [symbol] 7 | 38 [symbol] 8 |
| | Protection | Change in polari- | — | 0.17 | 0.17 | 0.19 | 0.16 | 0.3 [symbol] | 10.24 |
| | function for | zation degree | | | | | | | |
| | coating-type | before and after | | | | | | | |
| | polarization | light resistance | | | | | | | |
| | element | [symbol] est | | | | | | | |
| | | Judgement | — | ◯ | ◯ | ◯ | ◯ | X | X |

| | | | | | | | |
|---|---|---|---|---|---|---|---|
| Overall evaluation | — | ◯ | ◯ | ◯ | X | X | X |

[symbol]

indicates data missing or illegible when filed

Based on the results of the above Examples and the tests conducted to date by the present inventors, it was found that the transmittance at a wavelength of 400 nm was required to be lower than that at least in Comparative Example 1 to prevent the coating-type polarization element from deteriorating polarization performance over time due to exposure.

Based on the results of the above Examples and the tests conducted to date by the present inventors, it was found that when the adhesive layer formed from the adhesive composition containing the (meth)acrylic polymer (A) and the ultraviolet absorber (B) had a transmittance at a wavelength of 400 nm of 50% or less, the adhesive composition could be used in combination with a coating-type polarization element to prevent the coating-type polarization element from deteriorating polarization performance over time due to exposure.

### Example II-1

An adhesive composition II-1 was prepared by uniformly mixing 200 parts by mass of the (meth)acrylic polymer (A-1) solution (dilution solvent: ethyl acetate, solid content concentration of 50% by mass), 6 parts by mass of the hydroxy group-containing benzophenone compound (B1-1), 3 parts by mass of the photocleavage-type radical polymerization initiator (C-1), 25 parts by mass of the polyfunctional (meth)acrylate (D-1), 0.3 part by mass of 3-glycidoxypropyl methyl diethoxysilane (KBM-403, manufactured by Shin-Etsu Silicone) as a silane coupling agent, 0.3 part by mass of 1,2,3-triazole as a rust inhibitor, and 101 parts by mass of ethyl acetate.

The adhesive composition II-1 after solvent drying was formed into a sheet shape on a silicone release-treated mold release film (Diafoil MRV, manufactured by Mitsubishi Chemical Corp.) having a thickness of 100 μm, so as to have a thickness of 50 μm.

Next, the sheet-shaped adhesive composition II-1 together with the mold release film was placed in a drying apparatus heated to 95° C. and held for 10 minutes to volatilize the solvent contained in the adhesive composition II-1.

Then, a silicone release-treated mold release film (Diafoil MRQ, manufactured by Mitsubishi Chemical Corp.) having a thickness of 75 μm was laminated on the sheet-shaped adhesive composition II-1 after drying the solvent to form a laminate, and the adhesive composition II-1 was irradiated with light through the mold release film using a high-pressure mercury lamp, such that the accumulative irradiation amount at a wavelength of 365 nm was 1,000 mJ/cm² and the accumulative irradiation amount at a wavelength of 405 nm was 1,400 mJ/cm², thereby obtaining an adhesive sheet II-1 with mold release films (adhesive sheet thickness of 50 μm) having mold release films laminated on both front and back sides.

### Examples II-2 to II-3, Reference Example II-1, and Comparative Examples II-1 to II-2

Adhesive compositions II-2 to II-6 and adhesive sheets II-2 to II-6 with mold release films were prepared in the same manner as in Example II-1, except that the types and amounts of the (meth)acrylic polymer (A), the ultraviolet absorber (B), the radical polymerization initiator (C), the polyfunctional (meth)acrylate (D), and other additives used were those shown in Table 2.

<Evaluation>

The adhesive compositions II-1 to II-6 and the adhesive sheets II-1 to II-6 obtained in Examples, Reference Example, and Comparative Examples were measured and evaluated as follows.

[Light Transmittance]

The mold release films on both sides of the adhesive sheet with mold release films prepared in each of Examples, Reference Example, and Comparative Examples were sequentially peeled off; and the adhesive sheet (thickness of 50 μm) was adhered so as to be sandwiched between two sheets of soda lime glass (thickness of 0.5 mm) and subjected to an autoclave treatment (60° C., gauge pressure of 0.2 MPa, and 20 minutes) for finishing adhesion, thereby preparing a sample for optical property evaluation.

The light transmittance in the wavelength range of 360 nm to 430 nm of the prepared sample for optical property evaluation was measured using a spectrophotometer (apparatus name “UV2450”, manufactured by Shimadzu Corp.).

[b* Value]

The b* value of the prepared sample for optical property evaluation was measured using a spectrocolorimeter (apparatus name “SC-P”, manufactured by Suga Test Instruments Co., Ltd.) in accordance with JIS Z 8781-4.

[Gel Fraction]

The gel fraction of the adhesive composition prepared in each of Examples, Reference Example, and Comparative Examples was measured by the following procedure:
1) the adhesive composition was weighed (W1), and wrapped in a pre-weighed SUS mesh (W0);
2) the SUS mesh was immersed in 100 mL of ethyl acetate for 24 hours;
3) the SUS mesh was taken out and dried at 75° C. for 4.5 hours; and
4) the mass after drying (W2) was measured, and the gel fraction of the adhesive composition was determined by the following formula.

Gel fraction (%)=100×(W2−W0)/W1

[Adhesive Force]

For the adhesive sheet with mold release films prepared in each of Examples, Reference Example, and Comparative Examples, one of the mold release films was peeled off, and a polyethylene terephthalate film (“Cosmoshine A4300” with a thickness of 100 μm, manufactured by TOYOBO Co., Ltd.) serving as a backing film was roll-pressed thereon using a hand roller. This was cut into a strip shape of 10 mm width×100 mm length, and the adhesive surface exposed by peeling off the remaining mold release film was roll-bonded on a sheet of soda lime glass using a hand roller. The laminate was subjected to an autoclave treatment (60° C., gauge pressure of 0.2 MPa, and 20 minutes) for finishing adhesion to prepare an adhesive force measurement sample.

Using a universal material testing system (apparatus name “5965”, manufactured by Instron), the adhesive sheet was peeled off from the glass while pulling the backing film at an angle of 180° and a peeling speed of 60 mm/min, and the tensile strength was measured using a load cell to determine the 180° peel strength (N/cm) of the adhesive sheet against the glass. The results are shown in Table 2 as “Adhesive force”.

[Durability]

The sample for optical property evaluation was tested for 100 hours under ultraviolet irradiation conditions at an illuminance of 60 W/cm² (300 nm to 400 nm) and a black panel temperature of 63° C. using a xenon light resistance tester (apparatus name “Suntest XPS+”, manufactured by ATLAS), and the b* value of the sample after the test was measured using a spectrocolorimeter (apparatus name “SC-P”, manufactured by Suga Test Instruments Co., Ltd.) in accordance with JIS Z 8781-4.

The samples were evaluated according to the following criteria.

◯ (good): Those having an amount of change in the b* value before and after the durability test of 3 or less.

X (poor): Those having an amount of change in the b* value before and after the durability test of more than 3.

[Protection Function for Image Display Device Constituting Member]

For the adhesive sheet with mold release films prepared in each of Examples, Reference Example, and Comparative Examples, one of the mold release films was peeled off, the adhesive sheet was roll-pressed on the image display device constituting member using a hand roller, and the adhesive surface exposed by peeling off the remaining mold release film was roll-bonded on a sheet of soda lime glass using a hand roller. The laminate was subjected to an autoclave treatment (60° C., gauge pressure of 0.2 MPa, and 20 minutes) for finishing adhesion to prepare a sample for measuring a protection function for the image display device constituting member.

The sample was subjected to a light resistance test for 40 hours under ultraviolet irradiation conditions at an illuminance of 0.55 W/cm² (340 nm) using a xenon light resistance tester (apparatus name “Ci4000”, manufactured by ATLAS).

The value of the change in the polarization degree at a wavelength of 595 nm before and after the light resistance test (the polarization degree before the test—the polarization degree after the test) is shown in Table 2 as a result of the light resistance test.

Linearly polarized measurement light was made incident on the anisotropic dye film to measure “transmittance to polarization in the direction of absorption axis of the anisotropic dye film” and “transmittance to polarization in the direction of polarization axis of the anisotropic dye film” using a spectrophotometer equipped with a Glan-Thompson polarizer (product name “RETS-100”, manufactured by Otsuka Electronics Co., Ltd.), and the polarization degree (Pe) was calculated according to the following formula.

Pe=(Ty−Tz)/(Ty+Tz)

wherein Tz represents the transmittance to polarization in the direction of absorption axis of the anisotropic dye film; and Ty represents the transmittance to polarization in the direction of polarization axis of the anisotropic dye film.

The samples were evaluated according to the following criteria.

◯ (good): Those having an amount of change in the polarization degree before and after the light resistance test of 0.25 or less.

X (poor): Those having an amount of change in the polarization degree before and after the light resistance test of more than 0.25.

[Overall Evaluation]

Those judged as “◯ (good)” in both of the evaluations of the durability test and the protection function for image display device constituting member were judged as “◯ (good)”; and those judged as “X (poor)” in either or both of the evaluations of the durability test and the protection function for image display device constituting member were judged as “X (poor)”.

The results obtained by the measurement and evaluation are shown in Table 2.

TABLE 2

| | | | | Example | Example | Example | Reference | Comparative | Comparative |
|---|---|---|---|---|---|---|---|---|---|
| | | | | II-1 | II-2 | II-3 | Example II-1 | Example II-1 | Example II-2 |
| | | | | Adhesive | Adhesive | Adhesive | Adhesive | Adhesive | Adhesive |
| | | | | sheet | sheet | sheet | sheet | sheet | sheet |
| | | | | II-1 | II-2 | II-3 | II-4 | II-5 | II-6 |
| Compo- | (Meth)acrylic | A-1 | parts by mass | 100 | — | 100 | 100 | 100 | 100 |
| sition | polymer (A) | A-2 | parts by mass | — | 100 | — | — | — | — |
| | Ultraviolet | B1-1 | parts by mass | 6 | 6 | — | — | 1 | — |
| | absorber (B) | B1-2 | parts by mass | — | — | 6 | — | — | — |
| | | B-3 | parts by mass | — | — | — | 6 | — | — |
| | Radical | C-1 | parts by mass | 3 | 3 | 3 | 3 | 3 | 3 |
| | polymerization | | | | | | | | |
| | initiator (C) | | | | | | | | |
| | Polyfunctional | D-1 | parts by mass | 25 | — | 25 | 25 | 25 | 25 |
| | (meth)acrylate (D) | D-2 | parts by mass | — | 6 | — | — | — | — |
| | Others | Rust inhibitor | parts by mass | 0.3 | 0.3 | 0.3 | 0.3 | 0.3 | 0.3 |
| | | Silane coupling agent | parts by mass | 0.3 | 0.3 | 0.3 | 0.3 | 0.3 | 0.3 |
| Evalu- | Light | 360 nm | % | 0 | 0 | 0 | 0 | 4 | 59 |
| ation | transmittance | 370 nm | % | 0 | 0 | 0 | 0 | 8 | 68 |
| | | 380 nm | % | 0 | 0 | 0 | 0 | 20 | 73 |
| | | 390 nm | % | 2 | 2 | 0 | 0 | 43 | 80 |
| | | 400 nm | % | 20 | 22 | 19 | 15 | 64 | 83 |
| | | 410 nm | % | 60 | 61 | 65 | 60 | 82 | 88 |
| | | 420 nm | % | 83 | 82 | 85 | 82 | 89 | 90 |
| | | 430 nm | % | 88 | 88 | 90 | 88 | 90 | 90 |
| | Adhesive force | | N/cm | 6.1 | 6.1 | 10.6 | 6.8 | 6.8 | 6.0 |
| | Gel fraction | | % | [symbol] 1 | 71 | 49 | 46 | [symbol] 7 | [symbol] 6 |
| | T(380) × b′ | | — | 0.1 | 0.2 | 0.1 | 0.1 | 14. [symbol] | 31.2 |
| | T(430) × b′ | | — | 157.4 | 195.8 | 153.6 | 211.8 | 65.7 | 38.8 |
| | Durability | b′ (original) | — | 1.8 | 2.2 | 1.7 | 2.4 | 0.7 | 0.4 |
| | | b′ (after durability test) | — | 3.5 | 2.8 | 1.8 | 12.8 | 1.2 | 0.8 |
| | | change in b′ | — | 1.7 | 0.6 | 0.1 | 10.4 | 0.5 | 0.4 |
| | | (chromaticity) | | | | | | | |
| | | before and after | | | | | | | |
| | | durability test | | | | | | | |
| | | Judgement | — | ◯ | ◯ | ◯ | X | ◯ | ◯ |
| | Protection fuction | Change in polarization | — | 0.17 | 0.17 | 0.19 | 0.16 | 0.36 | 10.24 |
| | for image display | degree before and after | | | | | | | |
| | device constituting | light resistance test | | | | | | | |
| | member | Judgement | — | ◯ | ◯ | ◯ | ◯ | X | X |

| | | | | | | | |
|---|---|---|---|---|---|---|---|
| Overall evaluation | — | ◯ | ◯ | ◯ | X | X | X |

[symbol]

indicates data missing or illegible when filed

Based on the results of the above Examples and the tests conducted to date by the present inventors, it was found that the transmittance at a wavelength of 400 nm of less than 30% was required, at least in Reference Example II-1, to obtain excellent light resistance reliability.

### EXPLANATIONS OF LETTERS OR NUMERALS

1: Adhesive sheet for coating-type polarization elements, or adhesive sheet for image display device constituting members of the present invention
2: Cover glass or cover plastic
3: Coating-type polarization element (polarization layer) or optically anisotropic layer (polarization layer)
4: Orientation film
5: Coating-type polarization element (retardation layer) or optically anisotropic layer (retardation layer)
6: Polarization plate
7: Retardation plate
8: Liquid crystal panel
9: Organic EL panel
10: Resin sheet or glass
11a, 11b: Mold release film
12a to 12c: Pressure-sensitive adhesive layer or adhesive layer

1. An adhesive composition for coating-type polarization elements comprising a (meta)acrylic polymer (A), an ultraviolet absorber (B), and a radical polymerization initiator (C), wherein an adhesive layer formed from the adhesive composition has a transmittance at a wavelength of 400 nm of 50% or less.

2. The adhesive composition for coating-type polarization elements according to claim 1, further comprising a polyfunctional (meth)acrylate (D).

3. The adhesive composition for coating-type polarization elements according to claim 1, wherein a content of the ultraviolet absorber (B) is 0.1 part by mass or more relative to 100 parts by mass of the (meth)acrylic polymer.

4. The adhesive composition for coating-type polarization elements according to claim 1, wherein the ultraviolet absorber (B) comprises a benzophenone structure.

5. The adhesive composition for coating-type polarization elements according to claim 1, wherein the polyfunctional (meth)acrylate (D) comprises a (meth)acrylate oligomer having a molecular weight of 3,000 or more.

6. The adhesive composition for coating-type polarization elements according to claim 1, wherein the (meth)acrylic polymer (A) has a polymerizable carbon double bond group in a side chain.

7. The adhesive composition for coating-type polarization elements according to claim 1, wherein the radical polymerization initiator (C) comprises a photocleavage-type radical polymerization initiator.

8. The adhesive composition for coating-type polarization elements according to claim 1, being cured in multiple stages.

9. An adhesive sheet for coating-type polarization elements, comprising an adhesive layer formed using the adhesive composition for coating-type polarization elements according to claim 1.

10. The adhesive sheet for coating-type polarization elements according to claim 9, wherein a b* value is 10 or less.

11. The adhesive sheet for coating-type polarization elements according to claim 9, wherein a gel fraction is 20% or more and 95% or less.

12. The adhesive sheet for coating-type polarization elements according to claim 9, wherein a thickness is 10 μm or more and 175 μm or less.

13. An adhesive sheet with mold release films, comprising the adhesive sheet for coating-type polarization elements according to claim 9 laminated with mold release films.

14. A laminate sheet comprising a resin sheet containing, as a main component resin, one or more resins selected from the group consisting of cycloolefin resins, triacetyl cellulose resins, polymethyl methacrylate resins, epoxy resins, polyester resins, and polyimide resins, or a thin film glass on at least one surface of the adhesive sheet for coating-type polarization elements according to claim 9.

15. A coating-type polarization element with an adhesive layer, comprising an adhesive layer formed from the adhesive composition for coating-type polarization elements according to claim 1 on at least one surface of a coating-type polarization element.

16. An adhesive sheet with a polarization element, comprising a coating-type polarization element on at least one surface of the adhesive sheet for coating-type polarization elements according to claim 9.

17. An image display device, comprising a coating-type polarization element laminated directly or via other members with an adhesive layer, wherein the adhesive layer is formed from an adhesive composition containing a (meta)acrylic polymer (A), an ultraviolet absorber (B), and a radical polymerization initiator (C), and has a transmittance at a wavelength of 400 nm of 50% or less.

18. The image display device according to claim 17, wherein the adhesive layer has a transmittance at a wavelength of 380 nm of less than 20%.

19. The image display device according to claim 17, wherein the adhesive layer has a transmittance at a wavelength of 430 nm of 50% or more.

20. The image display device according to claim 17, wherein the adhesive layer satisfies the relationship of the following formulae (I) and (II) for a light transmittance T(380) at a wavelength of 380 nm, a light transmittance T(430) at a wavelength of 430 nm, and a b* value:
0≤T(380)×b*≤50 (I); and
70≤T(430)×b*≤220 (II).
